(19) United States
(12) Patent Application Publication
(10) Pub. No.: US 2024/0371827 A1
(43) Pub. Date: Nov. 7, 2024

(54) PACKAGE STRUCTURE AND METHOD OF FABRICATING THE SAME

(71) Applicant: Taiwan Semiconductor Manufacturing Company, Ltd., Hsinchu (TW)

(72) Inventors: Kai-Fung Chang, Taipei City (TW); Ching-Hua Hsieh, Hsinchu (TW); Yi-Yang Lei, Taichung City (TW); Chao-Wei Chiu, Hsinchu City (TW); Ming-Yu Yen, MiaoLi County (TW)

(73) Assignee: Taiwan Semiconductor Manufacturing Company, Ltd., Hsinchu (TW)

(21) Appl. No.: 18/311,243

(22) Filed: May 3, 2023

(51) Int. Cl. H01L 25/065; H01L 23/00; H01L 23/538

(52) U.S. Cl. CPC H01L 25/0655; H01L 23/5384; H01L 24/16; H01L 24/32; H01L 24/73; H01L 24/81; H01L 24/83; H01L 24/92; H01L 2224/16235; H01L 2224/32225; H01L 2224/73204; H01L 2224/81; H01L 2224/83; H01L 2224/9211

(57) ABSTRACT

A package structure includes a supporting base, conductive pillars, a first semiconductor die, a second semiconductor die, a first adhesive material, a second adhesive material and an isolation structure. The conductive pillars are disposed in the supporting base, and protruding out from a top surface of the supporting base. The second semiconductor die is adjacent to the first semiconductor die, wherein the first and second semiconductor dies are disposed on the supporting base and electrically connected to the conductive pillars. The first adhesive material is disposed in between the first semiconductor die and the top surface of the supporting base, and partially covering the conductive pillars. The second adhesive material is disposed in between the second semiconductor die and the top surface of the supporting base, and partially covering the conductive pillars. The isolation structure prevents a bleeding of the first and second adhesive material to an adjacent semiconductor die.

### BACKGROUND

Semiconductor devices and integrated circuits used in a variety of electronic applications, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 6 are schematic sectional and top views of various stages in a method of fabricating a semiconductor device according to some exemplary embodiments of the present disclosure.

FIG. 7A to FIG. 10 are schematic sectional and top views of various stages in a method of fabricating a semiconductor device according to some other exemplary embodiments of the present disclosure.

FIG. 11A to FIG. 15 are schematic sectional and top views of various stages in a method of fabricating a semiconductor device according to some other exemplary embodiments of the present disclosure.

FIG. 16 is a schematic sectional view of a semiconductor device in accordance with some embodiments of the present disclosure.

FIG. 17 to FIG. 21 are schematic sectional and top views of various stages in a method of fabricating a semiconductor device according to some other exemplary embodiments of the present disclosure.

FIG. 22 is a schematic sectional view of a semiconductor device in accordance with some other embodiments of the present disclosure.

FIG. 23 is a schematic sectional view of a semiconductor device in accordance with some other embodiments of the present disclosure.

FIG. 24 to FIG. 30 are schematic sectional views of various stages in a method of fabricating a package structure according to some exemplary embodiments of the present disclosure.

FIG. 31 is a schematic sectional view of a package structure in accordance with some other embodiments of the present disclosure.

FIG. 32 is a schematic sectional view of a package structure in accordance with some other embodiments of the present disclosure.

FIG. 33 is a schematic sectional view of a package structure in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

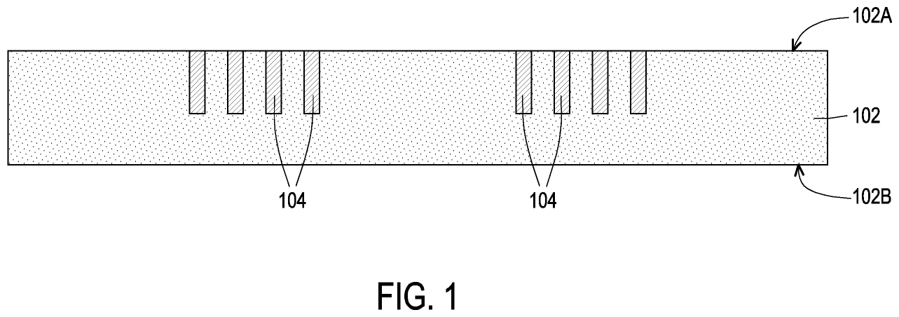

FIG. 1 to FIG. 6 are schematic sectional and top views of various stages in a method of fabricating a semiconductor device according to some exemplary embodiments of the present disclosure. Referring to FIG. 1, a supporting base 102 is provided. In some embodiments, the supporting base 102 is a semiconductor wafer, an interposer structure or a semiconductor substrate. In some embodiments, the supporting base 102 includes a first surface 102A (or top surface) and a second surface 102B (or bottom surface) opposite to the first surface 102A. For example, a plurality of conductive pillars 104 is disposed or embedded in the supporting base 102, while top surfaces of the conductive pillars 104 are exposed at the first surface 102A of the supporting base 102. The conductive pillars 104 are made of conductive materials such as copper, other metallic materials, or the like. In some embodiments, the supporting base 102 may include a substrate such as a bulk semiconductor substrate, silicon on insulator (SOI) substrate or a multi-layered semiconductor material substrate. The semiconductor material of the substrate (supporting base 102) may be silicon, germanium, silicon germanium, silicon carbide, gallium arsenic, gallium phosphide, indium phosphide, indium arsenide, indium antimonide, GaAsP, AlInAs, AlGaAs, GalnAs, GalnP, GaInAsP, or combinations thereof. In some embodiments, the supporting base 102 may be doped or undoped.

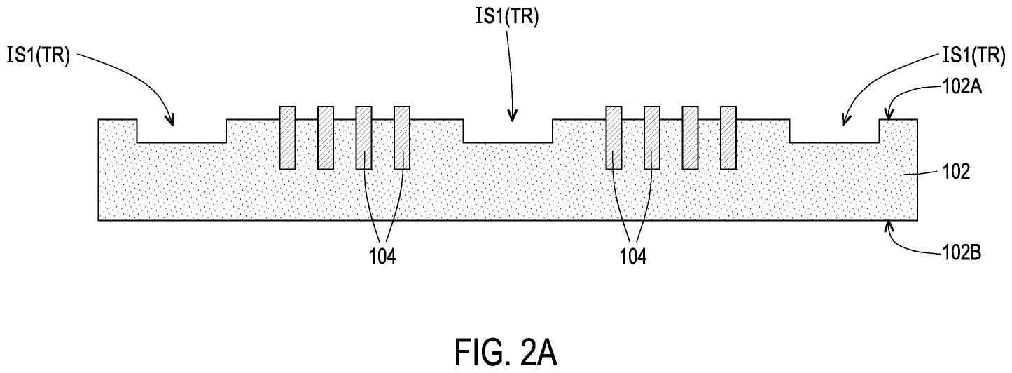

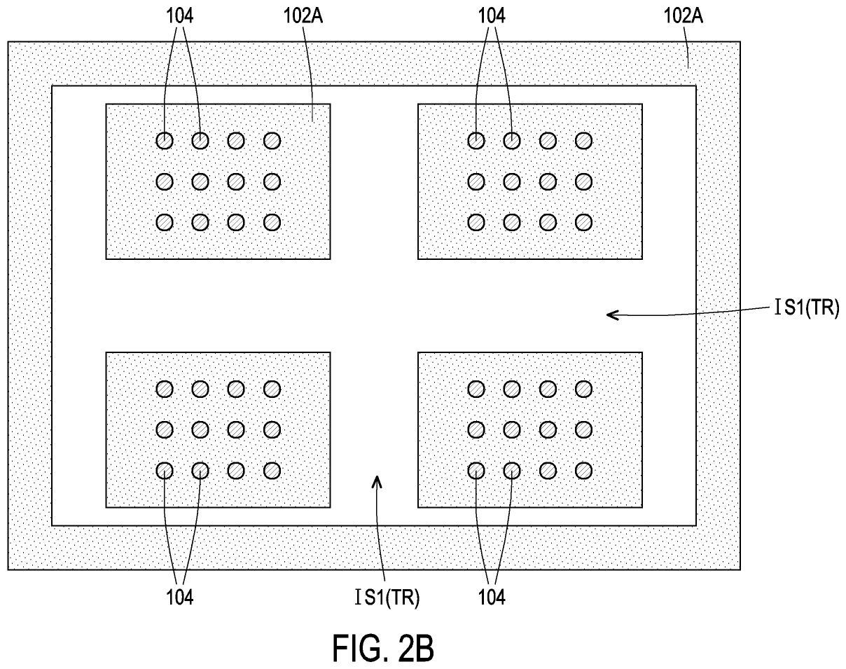

Referring to FIG. 2A, and from a top view of FIG. 2A as shown in FIG. 2B, portions of the supporting base 102 are removed from the first surface 102A so that the conductive pillars 104 are protruding out from the first surface 102A of the supporting base 102. For example, portions of the supporting base 102 are removed by etching, milling, laser drilling or the like. In some embodiments, other portions of the supporting base 102 may be further removed to form isolation structures IS1 (or bleeding prevention structure). In the exemplary embodiment, the isolation structures IS1 are isolation trenches TR that separate each of the semiconductor dies that will be bonded onto the conductive pillars 104 in subsequent steps. In other words, the isolation trenches TR may be formed to separate and surround each of the die bonding areas located in the first surface 102A of the supporting base 102. In a similar way, the isolation trenches TR may be formed by further removing portions of the supporting base 102 by etching, milling, laser drilling or the like.

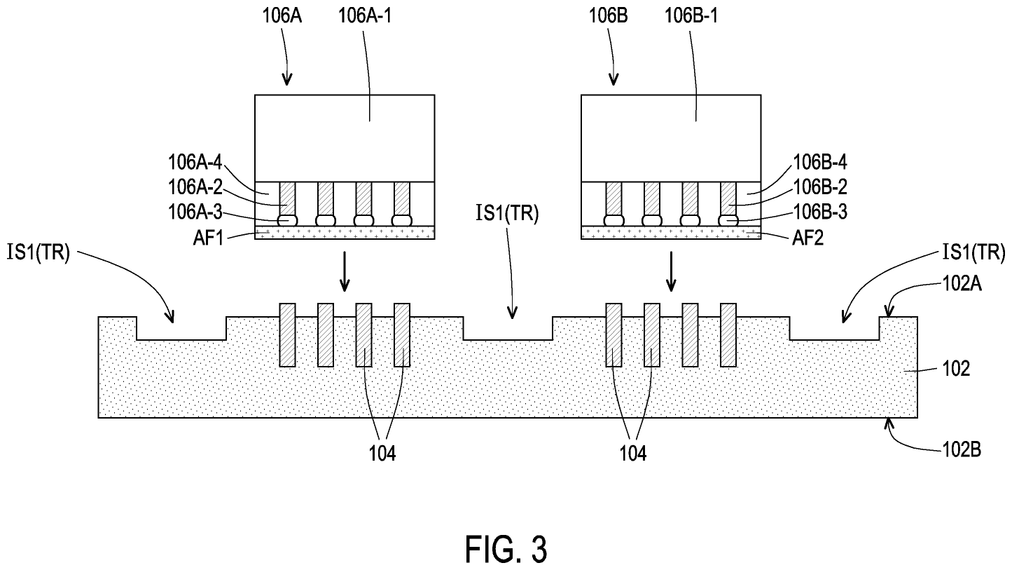

Referring to FIG. 3, in a subsequent step, a plurality of semiconductor dies (106A, 106B) are provided over the supporting base 102 for bonding to the conductive pillars 104. For example, at least a first semiconductor die 106A and a second semiconductor die 106B may be provided for bonding. Although two semiconductor dies are illustrated in FIG. 3, it is noted that two semiconductor dies, three semiconductor dies, four semiconductor dies or more semiconductor dies may be used for bonding to the conductive pillars 104 based on product requirement. In the exemplary embodiment, the first semiconductor die 106A, the second semiconductor die 106B and other semiconductor dies (if present) respectively include a semiconductor substrate (106A-1, 106B-1), a plurality of conductive posts (106A-2, 106B-2), a plurality of conductive bumps (106A-3, 106B-3) and a protection layer (106A-4, 106B-4).

As illustrated in FIG. 3, the semiconductor substrate (106A-1, 106B-1) may be a bulk silicon substrate or a silicon-on-insulator (SOI) substrate, and further includes active components (e.g., transistors or the like) and optionally passive components (e.g., resistors, capacitors, inductors or the like) formed therein. The conductive posts (106A-2, 106B-2) are disposed on the semiconductor substrate (106A-1, 106B-1), and include conductive materials such as copper, other metallic materials or the like. The conductive bumps (106A-3, 106B-3) are connected to the conductive posts (106A-2, 106B-2), and may include materials such as solder, or the like. In some embodiments, the protection layer (106A-4, 106B-4) is formed to surround and protect the conductive posts (106A-2, 106B-2) and the conductive bumps (106A-3, 106B-3). The protection layer (106A-4, 106B-4) may include materials such as benzocyclobutene (BCB), polyimide, polybenzoxazole (PBO) or a dielectric layer formed by other suitable polymers. As further illustrated in FIG. 3, a first adhesive material AF1 is formed over surfaces of the first semiconductor die 106A for bonding the first semiconductor die 106A to the conductive pillars 104. Similarly, a second adhesive material AF2 is formed over surfaces of the second semiconductor die 106B for bonding the second semiconductor die 106A to the conductive pillars 104. In some embodiments, the first adhesive material AF1 and the second adhesive material AF2 includes non-conductive films (NCF) or non-conductive pastes (NCP). For example, non-conductive films (NCF) or non-conductive pastes (NCP) generally include thermosetting polymers, thermoplastic polymers, curing agents, difunctional and multi-functional epoxies, silica fillers, or the like.

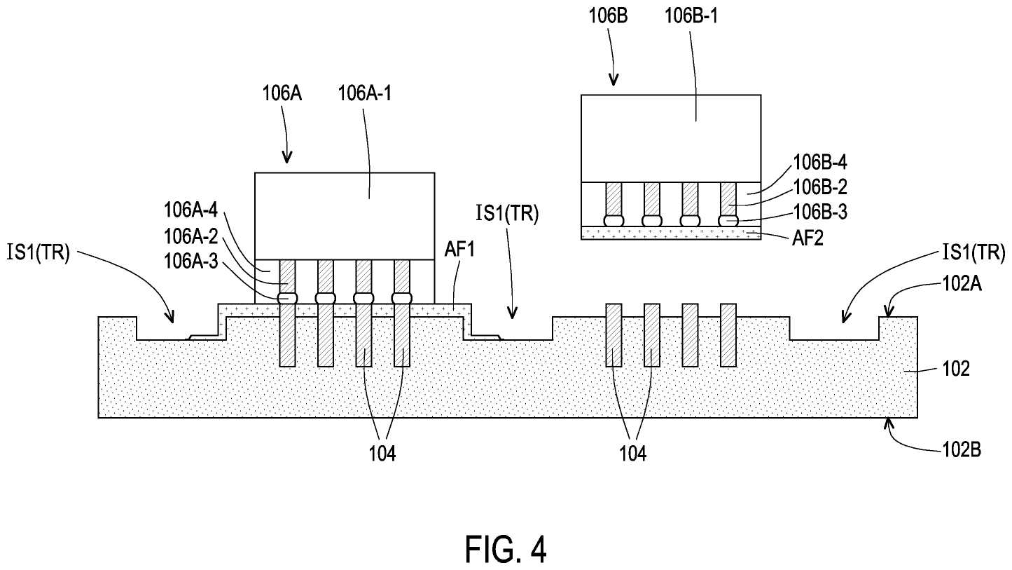

Referring to FIG. 4, in some embodiments, the first semiconductor die 106A is bonded to the conductive pillars 104 by joining the conductive bumps 106A-3 with the conductive pillars 104. In some embodiments, the first adhesive material AF1 will assist in the attachment of the conductive bumps 106A-3 with the conductive pillars 104. In certain embodiments, the first adhesive material AF1 is attached on the first surface 102A of the supporting base 102, and is partially covering the conductive pillars 104. In some embodiments, when the first semiconductor die 106A is pressed onto the supporting base 102, bleeding of the first adhesive material AF1 may occur, whereby the first adhesive material AF1 will bleed and flow into the isolation trenches TR. In other words, the first adhesive material AF1 is isolated by the isolation structures IS1 (or isolation trenches TR). Due to the presence of the isolation structures IS1 (or isolation trenches TR), the first adhesive material AF1 will not flow towards a bonding area of the second semiconductor die 106B (or any adjacent semiconductor dies). As such, a risk of tilt, cold joint or voids during the bonding of the second semiconductor die 106B with the conductive pillars 104 may be prevented.

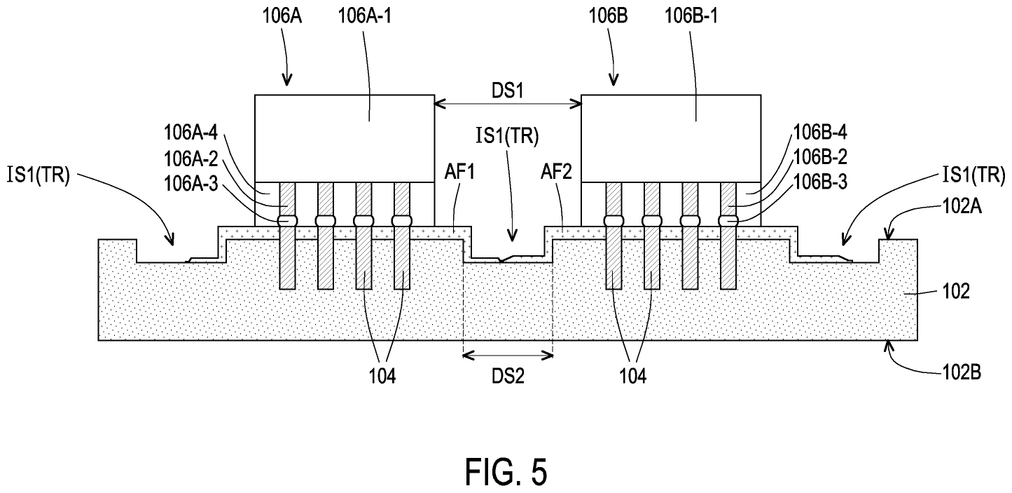

Referring to FIG. 5, after bonding the first semiconductor die 106A with the conductive pillars 104, the second semiconductor die 106B is bonded to the conductive pillars 104 by joining the conductive bumps 106B-3 with the conductive pillars 104. In some embodiments, the second adhesive material AF2 will assist in the attachment of the conductive bumps 106B-3 with the conductive pillars 104. In certain embodiments, the second adhesive material AF2 is attached on the first surface 102A of the supporting base 102, and is partially covering the conductive pillars 104. In some embodiments, when the second semiconductor die 106B is pressed onto the supporting base 102, bleeding of the second adhesive material AF2 may occur, whereby the second adhesive material AF2 will bleed and flow into the isolation trenches TR. In other words, the second adhesive material AF2 is isolated by the isolation structures IS1 (or isolation trenches TR). In certain embodiments, the second adhesive material AF2 flow into the isolation trenches TR, and is attached to the first adhesive material AF1. In the exemplary embodiment, although both the first adhesive material AF1 and the second adhesive material AF2 are shown to fill into the isolation trenches TR, the disclosure is not limited thereto. For example, depending on the amount of the first adhesive material AF1 and the second adhesive material AF2 used, one of the first adhesive material AF1 or the second adhesive material AF2 may fill into the isolation trenches TR. In some alternative embodiments, bleeding of the first adhesive material AF1 and the second adhesive material AF2 may occur, while both the first adhesive material AF1 and the second adhesive material AF2 do not flow into the isolation trenches TR. Due to the presence of the isolation structures IS1 (or isolation trenches TR), the second adhesive material AF2 will not flow towards a bonding area of any adjacent semiconductor dies. As such, a risk of tilt, cold joint or voids during the bonding of adjacent semiconductor dies may be prevented.

As further illustrated in FIG. 5, in some embodiments, after bonding the semiconductor dies, the first semiconductor die 106A and the second semiconductor die 106B are spaced apart by a distance of DS1, and whereby a width of the isolation trenches TR is DS2. In the exemplary embodiment, the distance DS1 is greater than the width DS2. In some embodiments, the distance DS1 is in a range of 20 μm to 2500 μm. In certain embodiment, a ratio (DS1:DS2) of the distance DS1 to the width DS2 is in a range of 1:0.05 to 1:0.9. Furthermore, in certain embodiments, a depth of the isolation trenches TR is in a range of 1 μm to 200 μm. By designing the isolation trenches TR to include widths and depths in the above range, the overfill of the adhesive material (AF1, AF2) in the isolation trenches TR is ensured, and a bleeding of the adhesive material (AF1, AF2) to adjacent dies may be prevented.

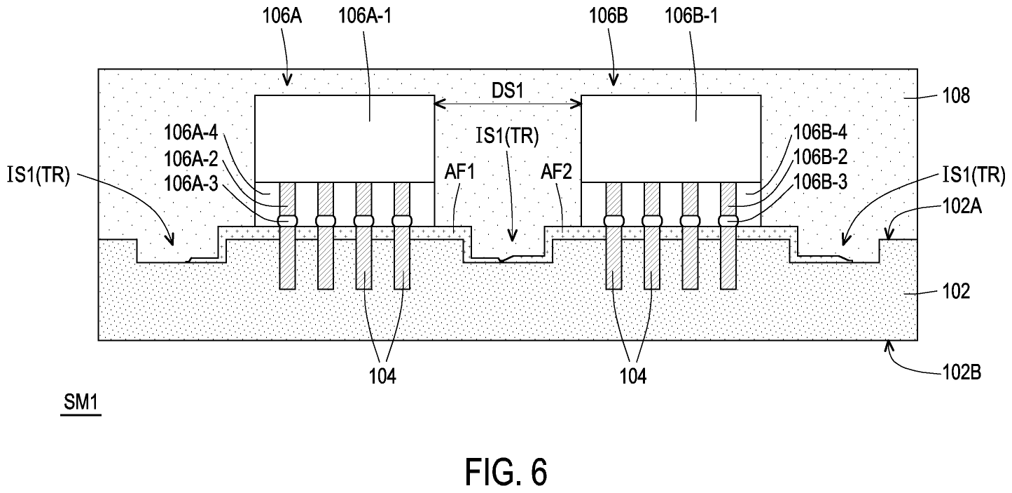

Referring to FIG. 6, after bonding the semiconductor dies (106A, 106B, or other semiconductor dies), an insulating encapsulant 108 is formed to encapsulate the first semiconductor die 106A and the second semiconductor die 106B. For example, the insulating encapsulant 108 laterally surrounds the first semiconductor die 106A and the second semiconductor die 106B, and fill up the isolation trenches TR. In some embodiments, the insulating encapsulant 108 may be physically contacting the supporting base 102 and physically contacting the first adhesive material AF1 and the second adhesive material AF2.

Furthermore, in some embodiments, the insulating encapsulant 108 is formed through, for example, a compression molding process or transfer molding. In one embodiment, a curing process is performed to cure the insulating encapsulant 108. In some embodiments, a material of the insulating encapsulant 108 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 108 may include an acceptable insulating encapsulation material. In some embodiments, the insulating encapsulant 108 may further include inorganic filler or inorganic compound (e.g. silica, clay, and so on) which can be added therein to optimize coefficient of thermal expansion (CTE) of the insulating encapsulant 108. The disclosure is not limited thereto. After forming the insulating encapsulant 108, a semiconductor device SM1 in accordance with some embodiments of the present disclosure is accomplished. In some embodiments, the semiconductor device SM1 is a semiconductor package or a chip-on-wafer (CoW) package.

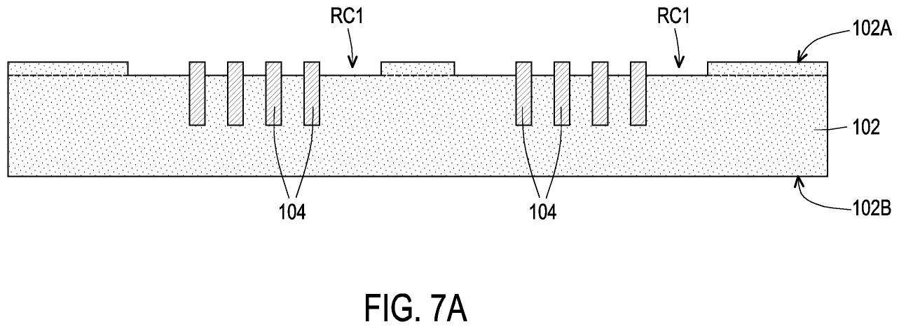

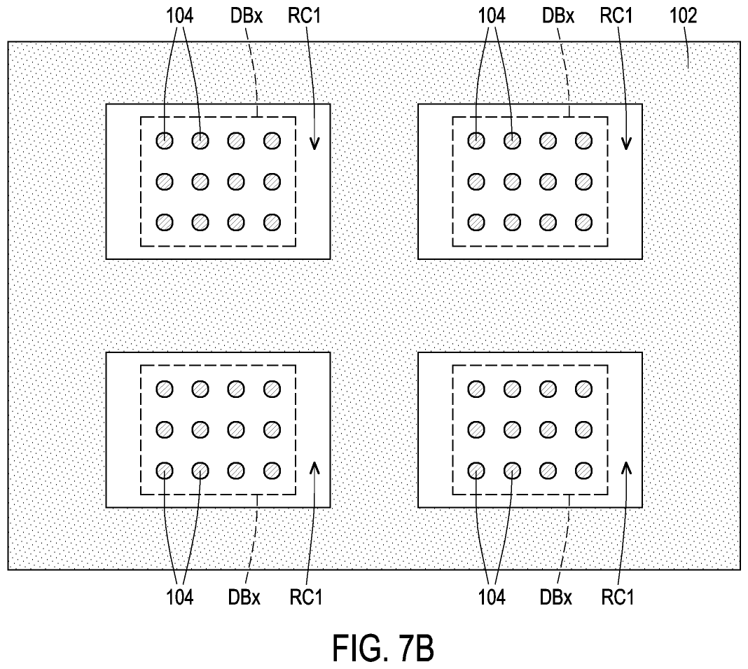

FIG. 7A to FIG. 10 are schematic sectional and top views of various stages in a method of fabricating a semiconductor device according to some other exemplary embodiments of the present disclosure. The method illustrated in FIG. 7A to FIG. 10 is similar to the method illustrated in FIG. 1 to FIG. 6. Therefore, the same reference numerals are used to refer to the same or liked parts, and its detailed description will not be repeated herein.

Referring to FIG. 7A, and from a top view of FIG. 7A as shown in FIG. 7B, after providing the same supporting base 102 with conductive pillars 104 as shown in FIG. 1, the first surface 102A of the supporting base 102 is further recessed to form recessed portions RC1. For example, portions of the supporting base 102 are removed so that the conductive pillars 104 are protruding out from the recessed portions RC1 at the first surface 102A of the supporting base 102. In some embodiments, a length and width of the recessed portions RC1 are greater than a length and width of a die bonding region DBx, in which semiconductor dies are bonded thereto in subsequent steps.

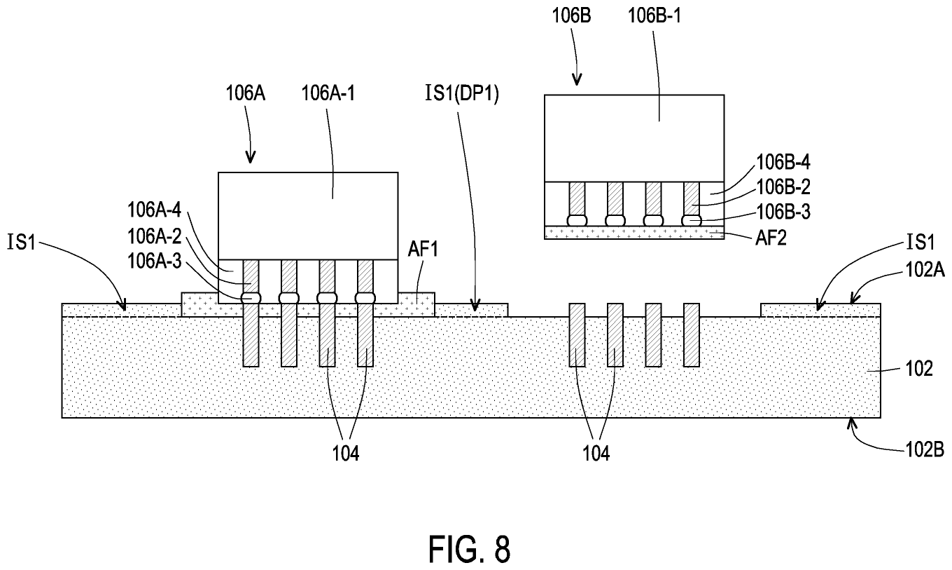

As illustrated in FIG. 8, after forming the recessed portions RC1, isolation structures IS1 may be formed in the supporting base 102. In the exemplary embodiment, the isolation structures IS1 include dam structures DP1 that separate adjacent die bonding regions DBx. In other words, after bonding semiconductor dies to the conductive pillars 104, the isolation structures IS1 (or dam structures DP1) may separate the adjacent semiconductor dies (106A, 106B). As shown in FIG. 8, in some embodiments, the first semiconductor die 106A is bonded to the conductive pillars 104 by joining the conductive bumps 106A-3 with the conductive pillars 104. In some embodiments, the first adhesive material AF1 will assist in the attachment of the conductive bumps 106A-3 with the conductive pillars 104. In the exemplary embodiment, when the first semiconductor die 106A is pressed onto the supporting base 102, bleeding of the first adhesive material AF1 may occur. However, the bleeding or flow of the first adhesive material AF1 is blocked by the isolation structures IS1 (or dam structures DP1). In other words, the first adhesive material AF1 is isolated by the isolation structures IS1 (or dam structures DP1). Due to the presence of the isolation structures IS1 (or dam structures DP1), the first adhesive material AF1 will not flow towards the die bonding region DBx of the second semiconductor die 106B (or any adjacent semiconductor dies). As such, a risk of tilt, cold joint or voids during the bonding of the second semiconductor die 106B with the conductive pillars 104 may be prevented. In some embodiments, the first adhesive material AF1 is filled into the recessed portions RC1 and is in physical contact with sidewalls of the first semiconductor die 106A. In certain embodiments, the first adhesive material AF1 is in physical contact with sidewalls of the isolation structures IS1 (or dam structures DP1).

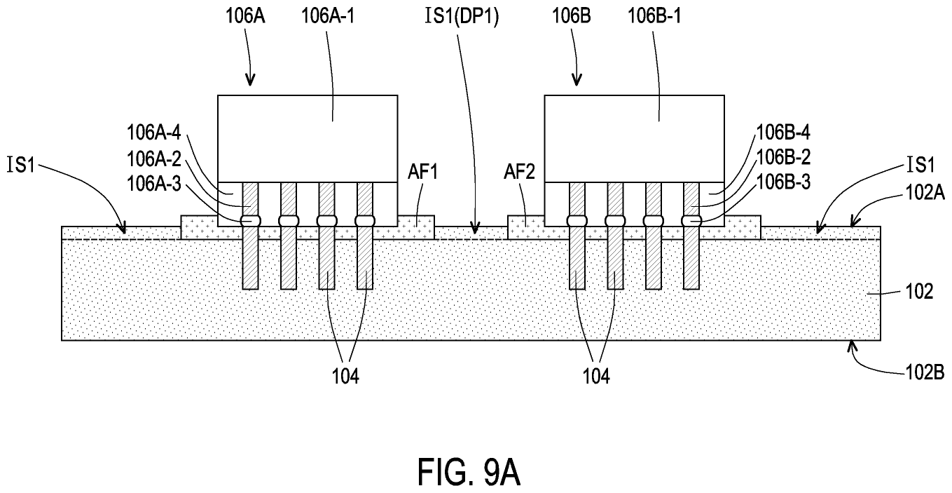

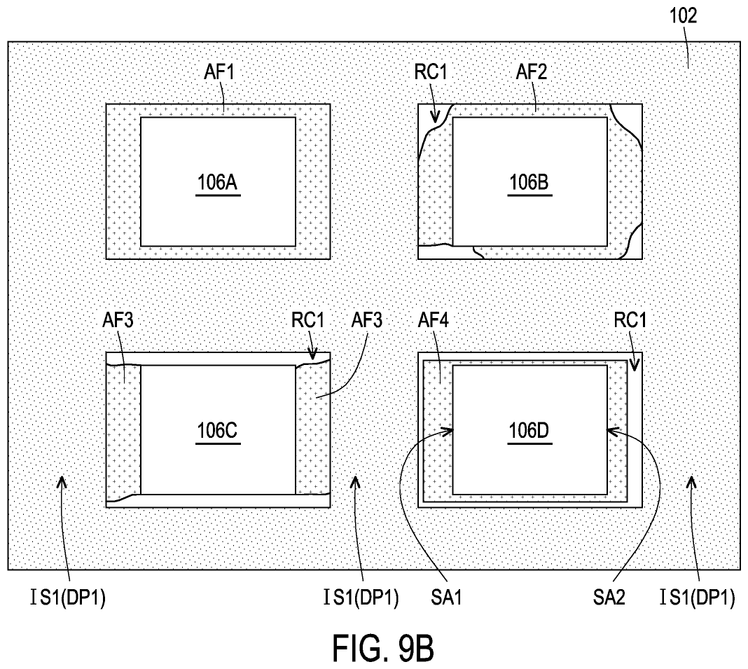

Referring to FIG. 9A, in a subsequent step, the second semiconductor die 106B is bonded to the conductive pillars 104 by joining the conductive bumps 106B-3 with the conductive pillars 104. In some embodiments, the second adhesive material AF2 will assist in the attachment of the conductive bumps 106B-3 with the conductive pillars 104. In the exemplary embodiment, when the second semiconductor die 106B is pressed onto the supporting base 102, bleeding of the second adhesive material AF2 may occur. However, the bleeding or flow of the second adhesive material AF2 is blocked by the isolation structures IS1 (or dam structures DP1). In other words, the second adhesive material AF2 is isolated by the isolation structures IS1 (or dam structures DP1). Due to the presence of the isolation structures IS1 (or dam structures DP1), the second adhesive material AF2 will not flow towards the die bonding region DBx of any adjacent semiconductor dies. As such, a risk of tilt, cold joint or voids during the bonding of adjacent semiconductor dies may be prevented. In some embodiments, the second adhesive material AF2 is filled into the recessed portions RC1 and is in physical contact with sidewalls of the second semiconductor die 106A. In certain embodiments, the second adhesive material AF2 is in physical contact with sidewalls of the isolation structures IS1 (or dam structures DP1).

Referring to FIG. 9B, which is a top view of the structure shown in FIG. 9A, in some embodiments, a third semiconductor die 106C and a fourth semiconductor die 106D are bonded to the conductive pillars 104 in the same way as illustrated for the first semiconductor die 106A and the second semiconductor die 106B. For example, the third semiconductor die 106C is bonded to the conductive pillars 104 with a third adhesive material AF3, while the fourth semiconductor die 106D is bonded to the conductive pillars 104 with a fourth adhesive material AF4. The third adhesive material AF3 and the fourth adhesive material AF4 include similar materials as with the first adhesive material AF1 and the second adhesive material AF2. Thus, its details will not be repeated herein.

As further illustrated in FIG. 9B, in some embodiments, the isolation structures IS1 (or dam structures DP1) are surrounding four sidewalls of each of the semiconductor dies (106A˜106D). In the exemplary embodiment, the first adhesive material AF1 may fill up the recessed portions RC1, and contact four sidewalls of the isolation structures IS1 (or dam structures DP1). However, the disclosure is not limited thereto. For example, the second adhesive material AF2 may partially fill up the recessed portions RC1 of the supporting base 102, while some of the recessed portions RC1 of the supporting base 102 is exposed by the second adhesive material AF2. Although the first adhesive material AF1 and the second adhesive material AF2 are shown to cover and surround four sidewalls of the corresponding semiconductor dies (106A or 106B), depending on the amount of adhesive material used, the adhesive material may be covering one, two or three sidewalls of the corresponding semiconductor dies. For example, as illustrated in FIG. 9B, the third adhesive material AF3 is covering two opposing sidewalls of the third semiconductor die 106C, while the remaining two sidewalls of the third semiconductor die 106C are exposed. In some embodiments, the fourth adhesive material AF4 is covering four sidewalls of the fourth semiconductor die 106D. However, the fourth adhesive material AF4 extends over a first sidewall SA1 of the fourth semiconductor die 106D by a first distance, and extends over a second sidewall SA2 of the fourth semiconductor die 106D by a second distance. For example, the first distance is greater than the second distance.

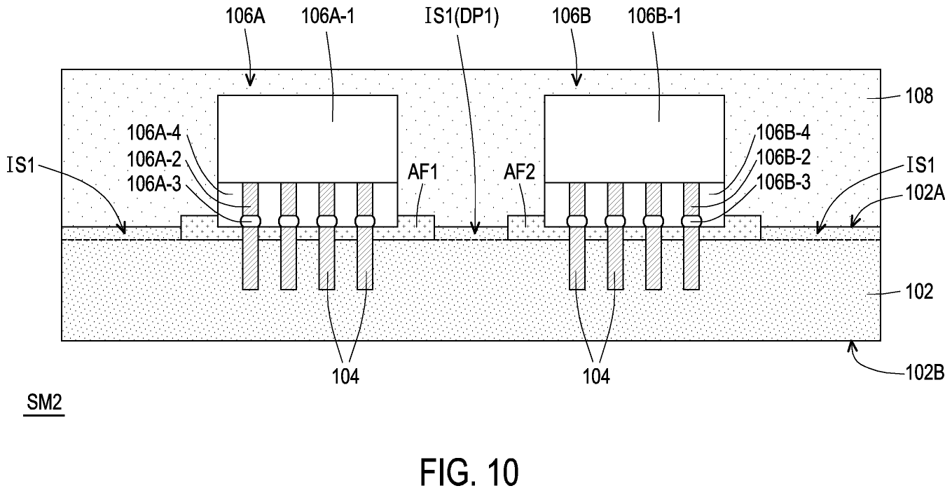

Referring to FIG. 10, after bonding the semiconductor dies (106A˜106D) to the conductive pillars 104, the insulating encapsulant 108 is formed to encapsulate the semiconductor dies (106A˜106D). After forming the insulating encapsulant 108, a semiconductor device SM2 in accordance with some embodiments of the present disclosure is accomplished. In the semiconductor device SM2, since the isolation structures IS1 (dam structures DP1) are used to prevent the bleeding of the adhesive material (AF1˜AF4) to adjacent dies, a risk of tilt, cold joint or voids during the bonding of adjacent dies can be prevented, and the semiconductor device SM2 may have improved reliability.

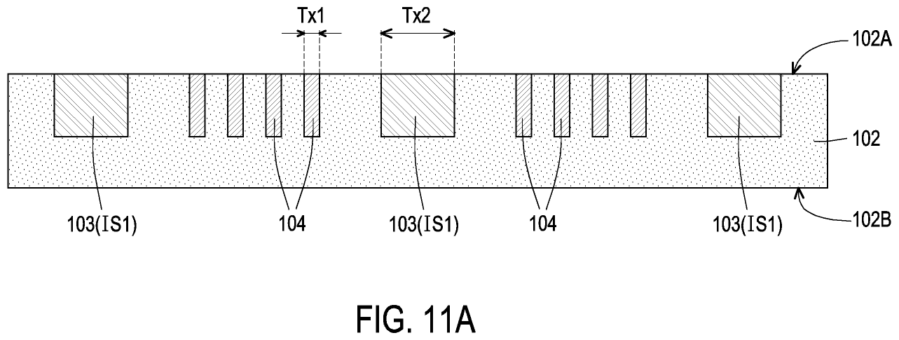

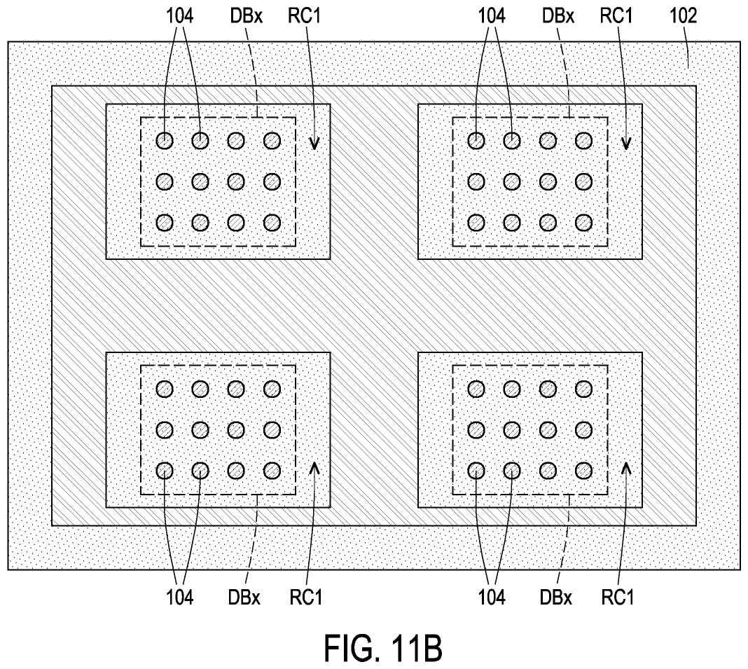

FIG. 11A to FIG. 15 are schematic sectional and top views of various stages in a method of fabricating a semiconductor device according to some other exemplary embodiments of the present disclosure. The method illustrated in FIG. 11A to FIG. 15 is similar to the method illustrated in FIG. 1 to FIG. 6. Therefore, the same reference numerals are used to refer to the same or liked parts, and its detailed description will not be repeated herein.

Referring to FIG. 11A, and from a top view of FIG. 11A as shown in FIG. 11B, a supporting base 102 is provided with conductive pillars 104 and metal dam structures 103 embedded therein. In some embodiments, the conductive pillars 104 and the metal dam structures 103 are embedded in the supporting base 102, while top surfaces of the conductive pillars 104 and the metal dam structures 103 are revealed. In some embodiments, the metal dam structures 103 are formed along with the conductive pillars 104 in the supporting base 102 in a single process. In certain embodiments, the metal dam structures 103 and the conductive pillars 104 are made of the same conductive materials. In alternative embodiments, the metal dam structures 103 and the conductive pillars 104 are made of different conductive materials.

As further illustrated in FIG. 11A and FIG. 11B, in some embodiments, the metal dam structures 103 are formed to surround the conductive pillars 104 located in separate die bonding regions DBx. For example, the die bonding regions DBx are regions where semiconductor dies are bonded thereto in subsequent steps. In some embodiments, the conductive pillars 104 have a thickness of Tx1, while the metal dam structures 103 have a thickness of Tx2, and the thickness Tx2 is greater than the thickness Tx1. However, in some alternative embodiments, the thickness Tx2 is substantially equal to the thickness Tx1, or the thickness Tx2 is smaller than the thickness Tx1. In other words, the thicknesses of the conductive pillars 104 and the metal dam structures 103 are not particularly limited, and may be adjusted based on product requirement.

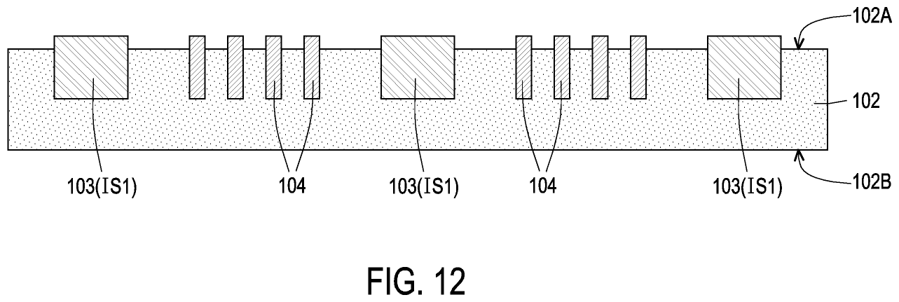

Referring to FIG. 12, in some embodiments, portions of the supporting base 102 are removed from the first surface 102A so that the conductive pillars 104 and the metal dam structures 103 are protruding out from the first surface 102A of the supporting base 102. For example, portions of the supporting base 102 are removed by etching, milling, laser drilling or the like. The protruded metal dam structures 103 are used as isolation structures IS1 (or bleeding prevention structure) to block the bleeding of the adhesive material during the die bonding steps.

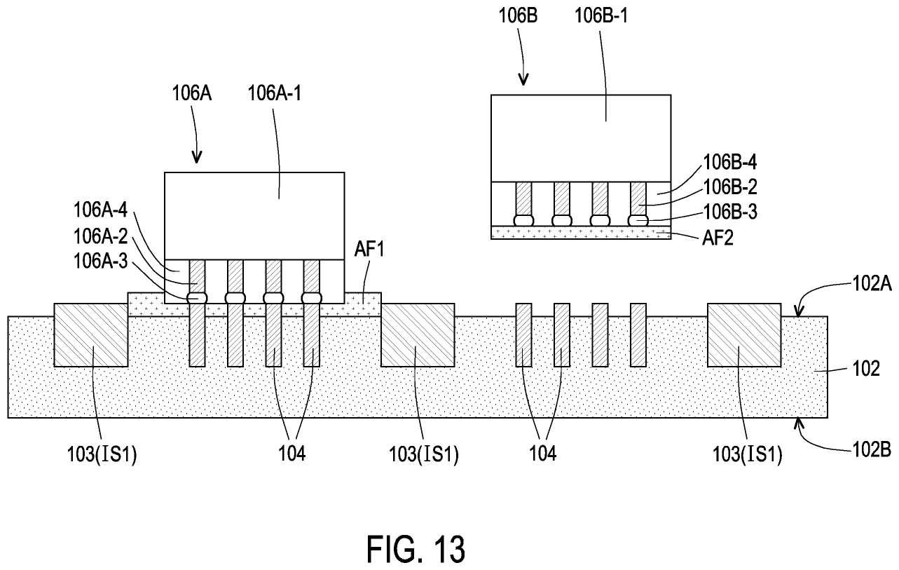

Referring to FIG. 13, in a subsequent step, the first semiconductor die 106A is bonded to the conductive pillars 104 by joining the conductive bumps 106A-3 with the conductive pillars 104. In some embodiments, the first adhesive material AF1 will assist in the attachment of the conductive bumps 106A-3 with the conductive pillars 104. In the exemplary embodiment, when the first semiconductor die 106A is pressed onto the supporting base 102, bleeding of the first adhesive material AF1 may occur. However, the bleeding or flow of the first adhesive material AF1 is blocked by the metal dam structures 103 (isolation structures IS1). In other words, the first adhesive material AF1 is isolated by the metal dam structures 103 (isolation structures IS1). Due to the presence of the metal dam structures 103, the first adhesive material AF1 will not flow towards the die bonding region DBx of the second semiconductor die 106B (or any adjacent semiconductor dies). As such, a risk of tilt, cold joint or voids during the bonding of the second semiconductor die 106B with the conductive pillars 104 may be prevented.

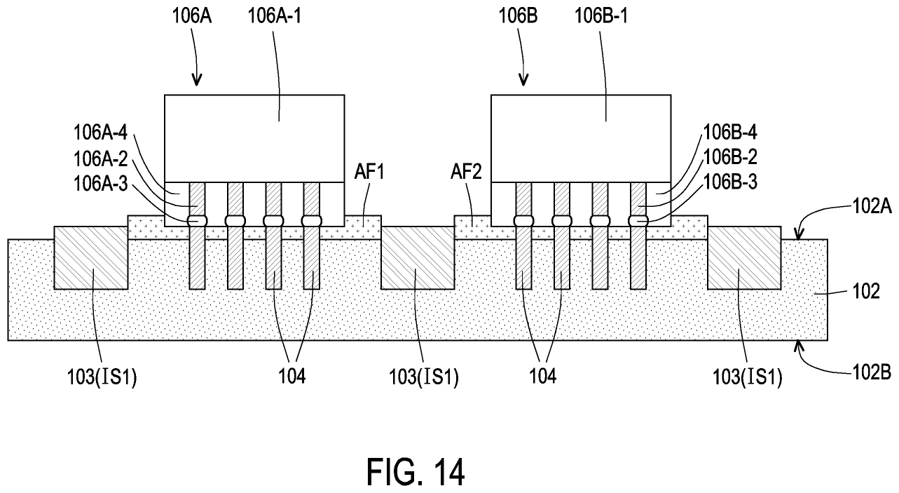

Referring to FIG. 14, in some embodiments, the second semiconductor die 106B is bonded to the conductive pillars 104 by joining the conductive bumps 106B-3 with the conductive pillars 104. In some embodiments, the second adhesive material AF2 will assist in the attachment of the conductive bumps 106B-3 with the conductive pillars 104. In the exemplary embodiment, when the second semiconductor die 106B is pressed onto the supporting base 102, bleeding of the second adhesive material AF2 may occur. However, the bleeding or flow of the second adhesive material AF2 is blocked by the metal dam structures 103 (isolation structures IS1). In other words, the second adhesive material AF2 is isolated by the metal dam structures 103. Due to the presence of the metal dam structures 103, the second adhesive material AF2 will not flow towards the die bonding region DBx of any adjacent semiconductor dies. As such, a risk of tilt, cold joint or voids during the bonding of adjacent semiconductor dies may be prevented.

Although not particularly illustrated in FIG. 14, third semiconductor dies 106C and fourth semiconductor dies 106D, or more semiconductor dies may be bonded to the conductive pillars 104 in the same way as described in FIG. 9B. In a similar way, the adhesive materials (AF1˜AF4) used for bonding the semiconductor dies (106A˜106D) to the conductive pillars 104 may have the various arrangement as shown in FIG. 9B. For example, the adhesive materials (AF1˜AF4) may be contacting the sidewalls of some of the metal dam structures 103, while being spaced apart from the sidewalls of some of the metal dam structures 103. Furthermore, the adhesive materials (AF1˜AF4) may be contacting and covering one or more sidewalls of each of the semiconductor dies (106A˜106D).

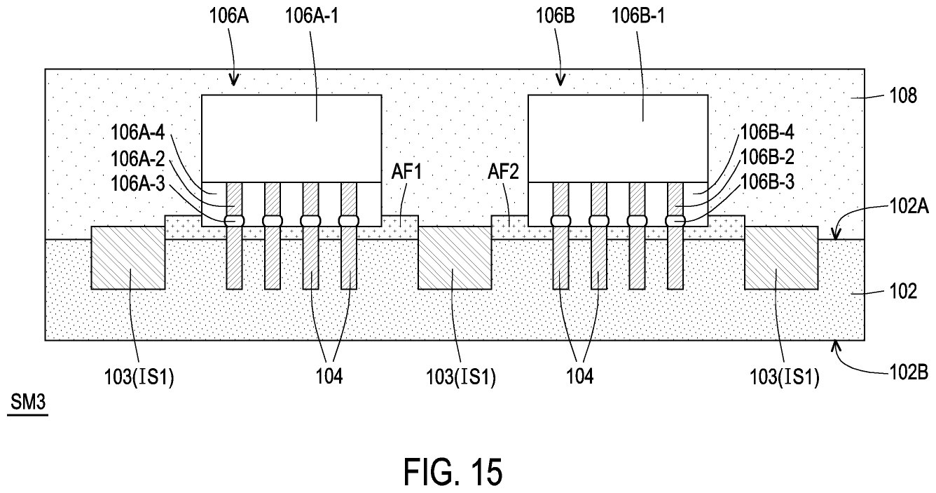

Referring to FIG. 15, after bonding the semiconductor dies (106A˜106D) to the conductive pillars 104, the insulating encapsulant 108 is formed to encapsulate the semiconductor dies (106A˜106D). After forming the insulating encapsulant 108, a semiconductor device SM3 in accordance with some embodiments of the present disclosure is accomplished. In the semiconductor device SM3, since metal dam structures 103 (isolation structures IS1) are used to prevent the bleeding of the adhesive material (AF1˜AF4) to adjacent dies, a risk of tilt, cold joint or voids during the bonding of adjacent dies can be prevented, and the semiconductor device SM3 may have improved reliability.

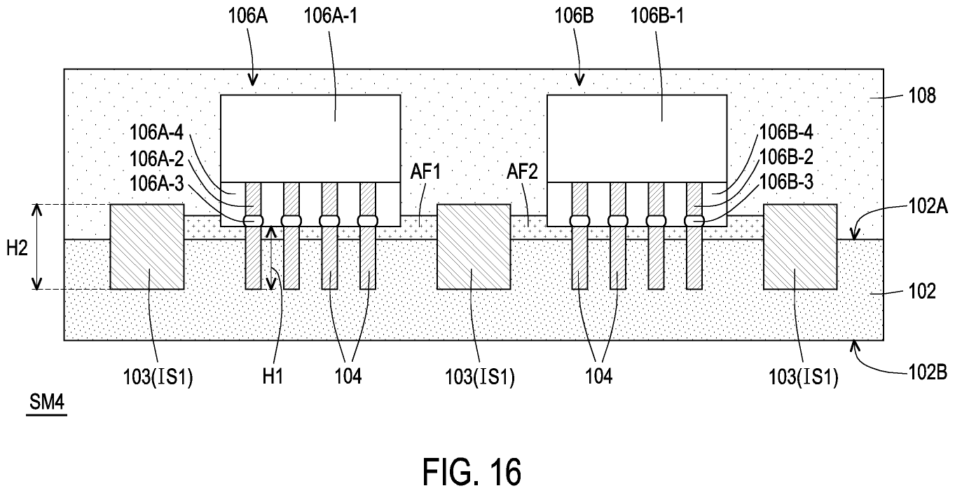

FIG. 16 is a schematic sectional view of a semiconductor device in accordance with some embodiments of the present disclosure. The semiconductor device SM4 illustrated in FIG. 16 is similar to the semiconductor device SM3 illustrated in FIG. 15. Therefore, the same reference numerals are used to refer to the same or like parts, and its detailed description will not be repeated herein. The difference between the embodiments is in the design of the metal dam structures 103. As illustrated in FIG. 16, in some embodiments, the conductive pillars 104 have a height of H1, while the metal dam structures 103 have a height of H2, wherein the height H2 is greater than the height H1. In certain embodiments, the metal dam structures 103 extend to a level higher than top surfaces of the conductive pillars 104. As such, when the semiconductor dies (106A˜106D) are pressed onto the supporting base 102, the isolation or blocking of the adhesive material (AF1˜AF4) to adjacent dies may be further ensured, and a risk of tilt, cold joint or voids during the bonding of adjacent dies can be prevented, and the semiconductor device SM4 may have improved reliability.

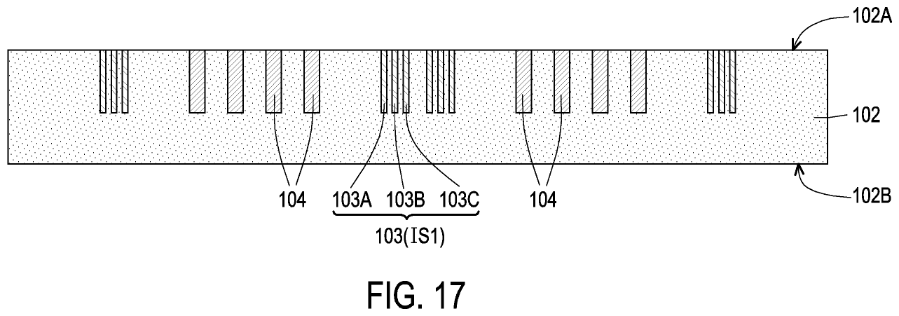

FIG. 17 to FIG. 21 are schematic sectional and top views of various stages in a method of fabricating a semiconductor device according to some other exemplary embodiments of the present disclosure. The method illustrated in FIG. 17 to FIG. 21 is similar to the method illustrated in FIG. 11A to FIG. 15. Therefore, the same reference numerals are used to refer to the same or like parts, and its detailed description will not be repeated herein.

As illustrated in FIG. 17, a supporting base 102 with conductive pillars 104 and metal dam structures 103 is provided. For example, the metal dam structures 103 includes a first metal dam portion 103A encircling the conductive pillars 104, a second metal dam portion 103B encircling the first metal dam portion 103A, and a third metal dam portion 103C encircling the second metal dam portion 103B. In some embodiments, the conductive pillars 104 and the metal dam structures 103 are embedded in the supporting base 102, while top surfaces of the conductive pillars 104 and the metal dam structures 103 are revealed.

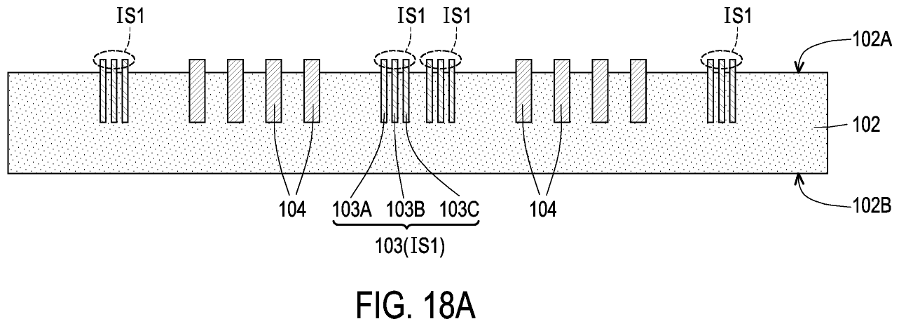

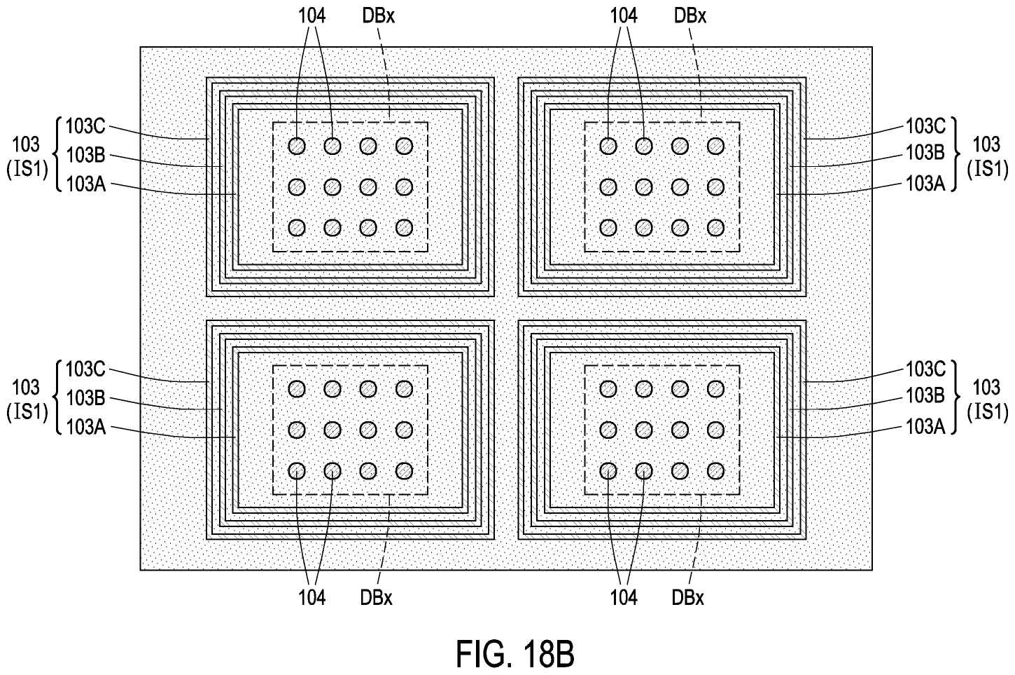

Referring to FIG. 18A, and from a top view of FIG. 18A as shown in FIG. 18B, in some embodiments, portions of the supporting base 102 are removed from the first surface 102A so that the conductive pillars 104 and the metal dam structures 103 (including metal dam portions 103A˜103C) are protruding out from the first surface 102A of the supporting base 102. For example, portions of the supporting base 102 is removed by etching, milling, laser drilling or the like. The protruded metal dam structures 103 are used as isolation structures IS1 (or bleeding prevention structure) to block the bleeding of the adhesive material during the die bonding steps. In the exemplary embodiment, the metal dam structures 103 (including metal dam portions 103A˜103C) are formed to surround the conductive pillars 104 located in separate die bonding regions DBx.

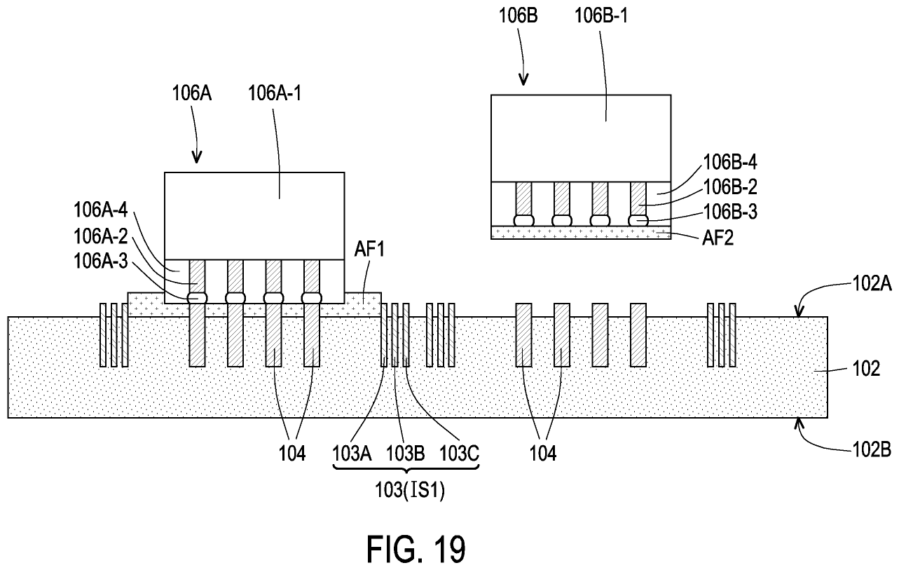

Referring to FIG. 19, in a subsequent step, the first semiconductor die 106A is bonded to the conductive pillars 104 by joining the conductive bumps 106A-3 with the conductive pillars 104. In some embodiments, the first adhesive material AF1 will assist in the attachment of the conductive bumps 106A-3 with the conductive pillars 104. In the exemplary embodiment, when the first semiconductor die 106A is pressed onto the supporting base 102, bleeding of the first adhesive material AF1 may occur. However, the bleeding or flow of the first adhesive material AF1 is blocked by the metal dam structures 103. For example, the first metal dam portion 103A is used as an initial barrier that blocks the bleeding of the first adhesive material AF1. In some embodiments, if the first adhesive material AF1 overflows across the first metal dam portion 103A, the second metal dam portion 103B and the third metal dam portion 103C may further prevent the bleeding of the first adhesive material AF1. In other words, the first adhesive material AF1 is isolated by the metal dam structures 103 (including metal dam portions 103A˜103C). Due to the presence of the metal dam structures 103, the first adhesive material AF1 will not flow towards the die bonding region DBx of the second semiconductor die 106B (or any adjacent semiconductor dies). As such, a risk of tilt, cold joint or voids during the bonding of the second semiconductor die 106B with the conductive pillars 104 may be prevented.

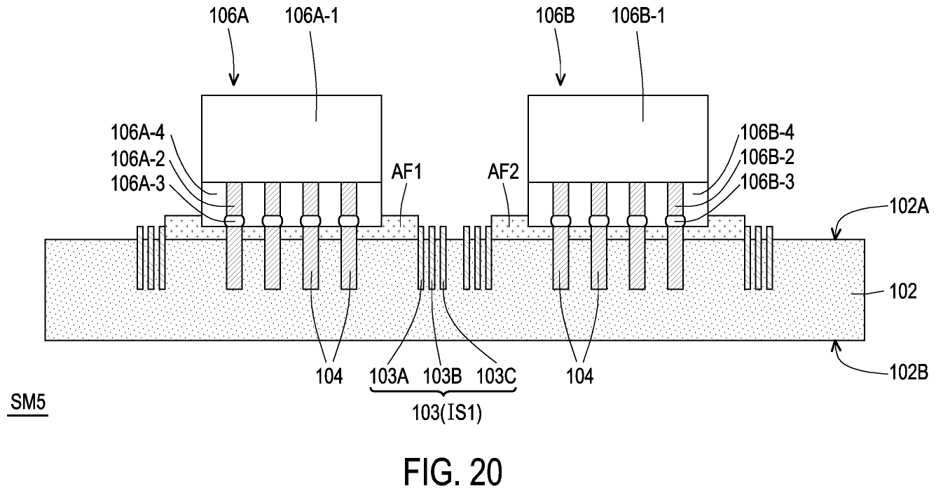

Referring to FIG. 20, in some embodiments, the second semiconductor die 106B is bonded to the conductive pillars 104 by joining the conductive bumps 106B-3 with the conductive pillars 104. In some embodiments, the second adhesive material AF2 will assist in the attachment of the conductive bumps 106B-3 with the conductive pillars 104. In the exemplary embodiment, when the second semiconductor die 106B is pressed onto the supporting base 102, bleeding of the second adhesive material AF2 may occur. However, the bleeding or flow of the second adhesive material AF2 is blocked by the metal dam structures 103 (including metal dam portions 103A˜103C). In other words, the second adhesive material AF2 is isolated by the metal dam structures 103. Due to the presence of the metal dam structures 103 (including metal dam portions 103A˜103C), the second adhesive material AF2 will not flow towards the die bonding region DBx of any adjacent semiconductor dies. As such, a risk of tilt, cold joint or voids during the bonding of adjacent semiconductor dies may be prevented. After bonding the second semiconductor die 106B to the conductive pillars 104, each of the first metal dam portions 103A will be encircling the first semiconductor die 106A and the second semiconductor die 106B, the second metal dam portions 103B are encircling the first metal dam portions 103A, while the third metal dam portions 103C are encircling the second metal dam portions 103B.

Although not particularly illustrated in FIG. 20, third semiconductor dies 106C and fourth semiconductor dies 106D, or more semiconductor dies may be bonded to the conductive pillars 104 in the same way as described in FIG. 9B. In a similar way, the adhesive materials (AF1˜AF4) used for bonding the semiconductor dies (106A˜106D) to the conductive pillars 104 may have the various arrangement as shown in FIG. 9B. For example, the adhesive materials (AF1˜AF4) may be contacting the sidewalls of some of the metal dam structures 103, while being spaced apart from the sidewalls of some of the metal dam structures 103. Furthermore, the adhesive materials (AF1˜AF4) may be contacting and covering one or more sidewalls of each of the semiconductor dies (106A˜106D).

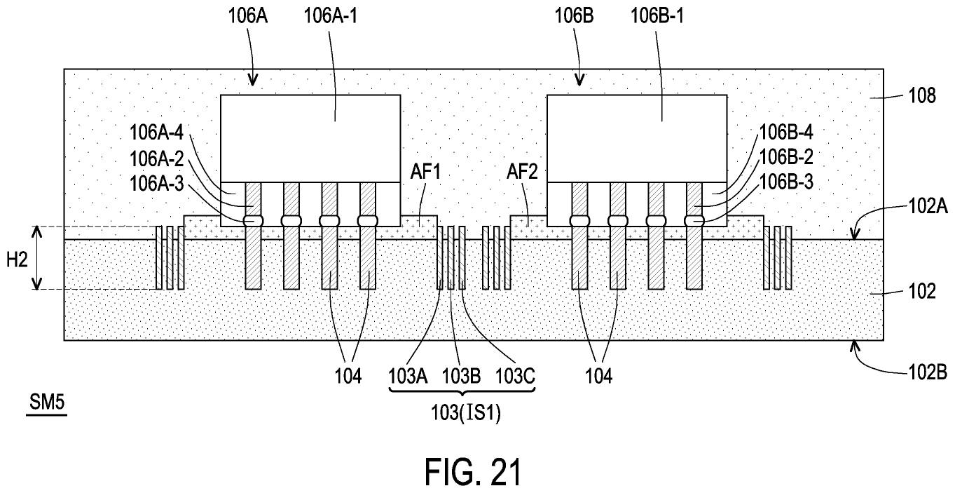

Referring to FIG. 21, after bonding the semiconductor dies (106A˜106D) to the conductive pillars 104, the insulating encapsulant 108 is formed to encapsulate the semiconductor dies (106A˜106D). After forming the insulating encapsulant 108, a semiconductor device SM5 in accordance with some embodiments of the present disclosure is accomplished. In the semiconductor device SM5, since metal dam structures 103 (including metal dam portions 103A˜103C) are used to prevent the bleeding of the adhesive material (AF1˜AF4) to adjacent dies, a risk of tilt, cold joint or voids during the bonding of adjacent dies can be prevented, and the semiconductor device SM5 may have improved reliability.

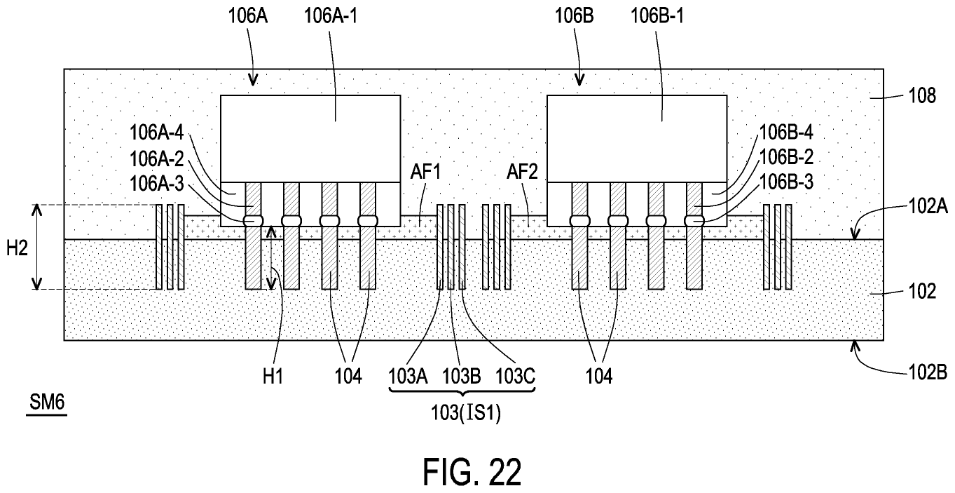

FIG. 22 is a schematic sectional view of a semiconductor device in accordance with some other embodiments of the present disclosure. The semiconductor device SM6 illustrated in FIG. 22 is similar to the semiconductor device SM5 illustrated in FIG. 21. Therefore, the same reference numerals are used to refer to the same or like parts, and its detailed description will not be repeated herein. The difference between the embodiments is in the design of the metal dam structures 103. As illustrated in FIG. 22, in some embodiments, the conductive pillars 104 have a height of H1, while each of the metal dam portions 103A˜103C have a height of H2, wherein the height H2 is greater than the height H1. In certain embodiments, the metal dam portions 103A˜103C of the metal dam structures 103 extend to a level higher than top surfaces of the conductive pillars 104. As such, when the semiconductor dies (106A˜106D) are pressed onto the supporting base 102, the isolation or blocking of the adhesive material (AF1˜AF4) to adjacent dies may be further ensured, and a risk of tilt, cold joint or voids during the bonding of adjacent dies can be prevented, and the semiconductor device SM6 may have improved reliability.

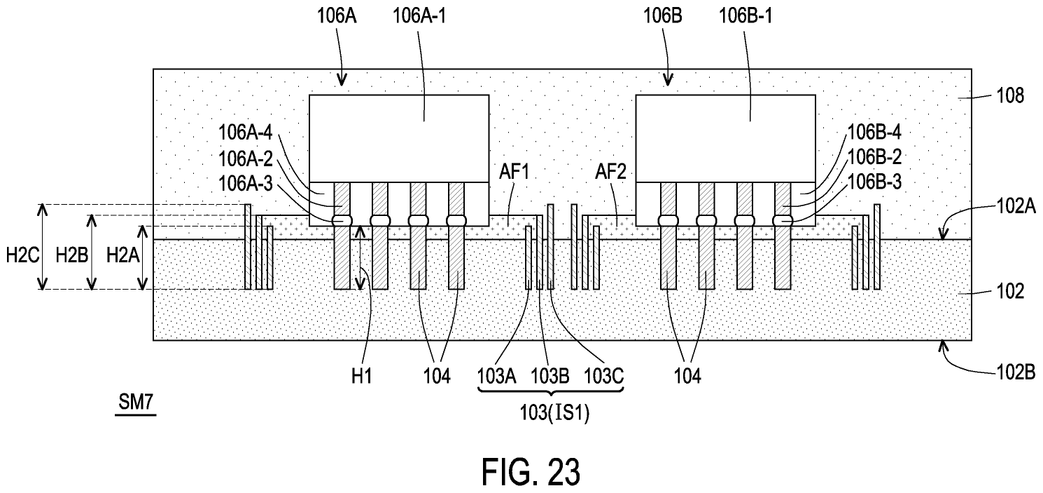

FIG. 23 is a schematic sectional view of a semiconductor device in accordance with some other embodiments of the present disclosure. The semiconductor device SM7 illustrated in FIG. 23 is similar to the semiconductor device SM6 illustrated in FIG. 22. Therefore, the same reference numerals are used to refer to the same or like parts, and its detailed description will not be repeated herein. The difference between the embodiments is in the design of the metal dam structures 103. As illustrated in FIG. 23, the conductive pillars 104 have a height of H1, while the metal dam portions 103A˜103C of the metal dam structures 103 have different heights. For example, the first metal dam portions 103A have a height of H2A, the second metal dam portions have a height of H2B, while the third metal dam portions have a height of H2C. In the exemplary embodiment, the height H2A is substantially equal to the height H1, the height H2B is greater than the height H2A, and the height H2C is greater than the height H2B.

In some embodiments, the first metal dam portion 103A is used as an initial barrier that blocks the bleeding of the first adhesive material AF1. In certain embodiments, when the first adhesive material AF1 overflows across the first metal dam portion 103A, the second metal dam portion 103B with greater height may further prevent the bleeding of the first adhesive material AF1. In some embodiments, the second metal dam portion 103B may be in contact with the first adhesive material AF1. Due to the presence of the metal dam structures 103 (including metal dam portions 103A˜103C), when the semiconductor dies (106A˜106D) are pressed onto the supporting base 102, the isolation or blocking of the adhesive material (AF1˜AF4) to adjacent dies may be further ensured, and a risk of tilt, cold joint or voids during the bonding of adjacent dies can be prevented, and the semiconductor device SM7 may have improved reliability.

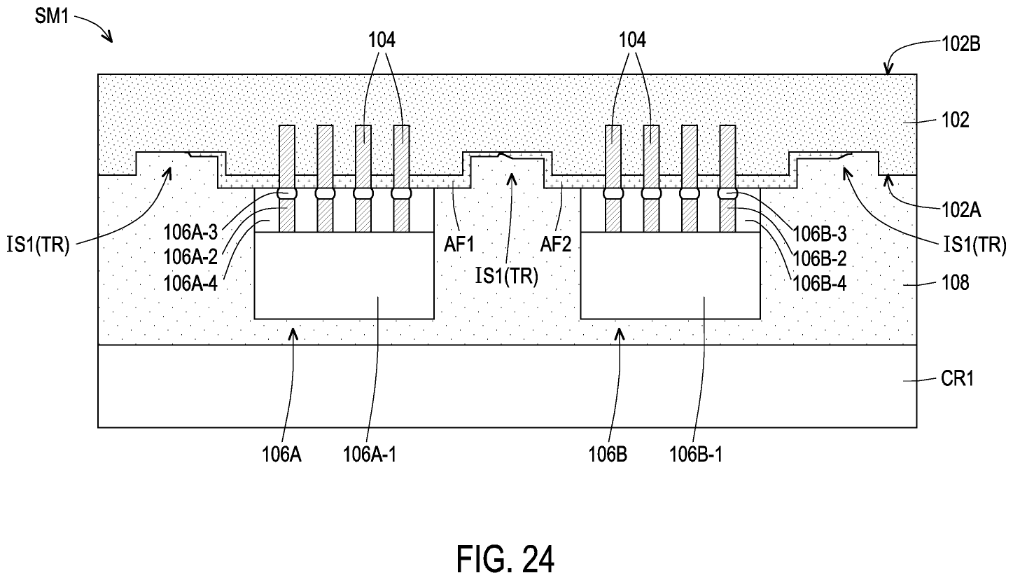

FIG. 24 to FIG. 30 are schematic sectional views of various stages in a method of fabricating a package structure according to some exemplary embodiments of the present disclosure. Referring to FIG. 24, the same steps illustrated in FIG. 1 to FIG. 6 may be performed to obtain the semiconductor device SM1. Thereafter, the semiconductor device SM1 obtained in FIG. 6 is turned upside down or flipped, and placed on a carrier CR1, so that the carrier CR1 directly contacts the insulating encapsulant 108. In the exemplary embodiment, the supporting base 102 is an interposer structure, and the second surface 102B of the supporting base 102 is revealed. At this stage, the conductive pillars 104 are not exposed, and are embedded in the supporting base 102.

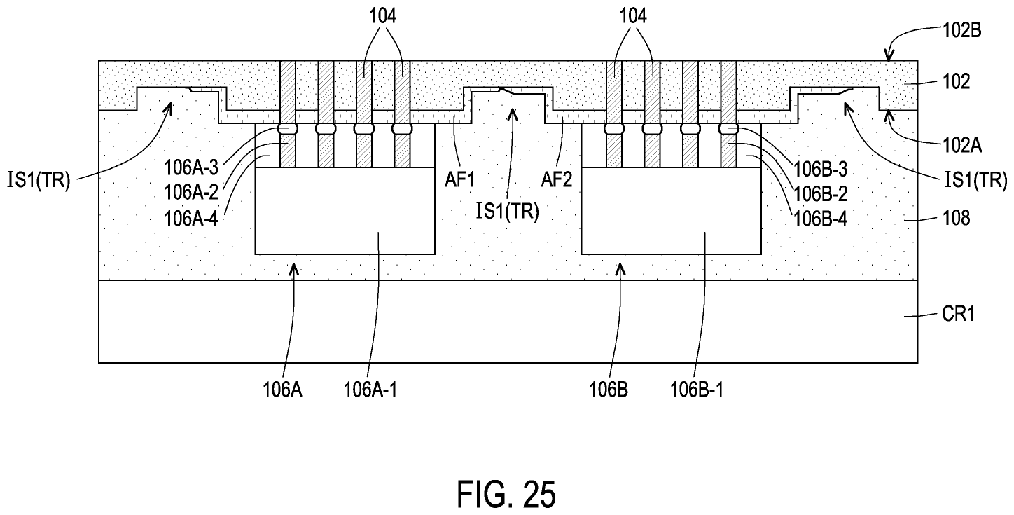

Referring to FIG. 25, a thinning process is performed on the second surface 102B of the supporting base 102 to partially remove or thin the supporting base 102. For example, the second surface 102B of the supporting base 102 is thinned until the conductive pillars 104 are exposed at the second surface 102B. In some embodiments, the thinning process may include a back-grinding process, a polishing process or an etching process.

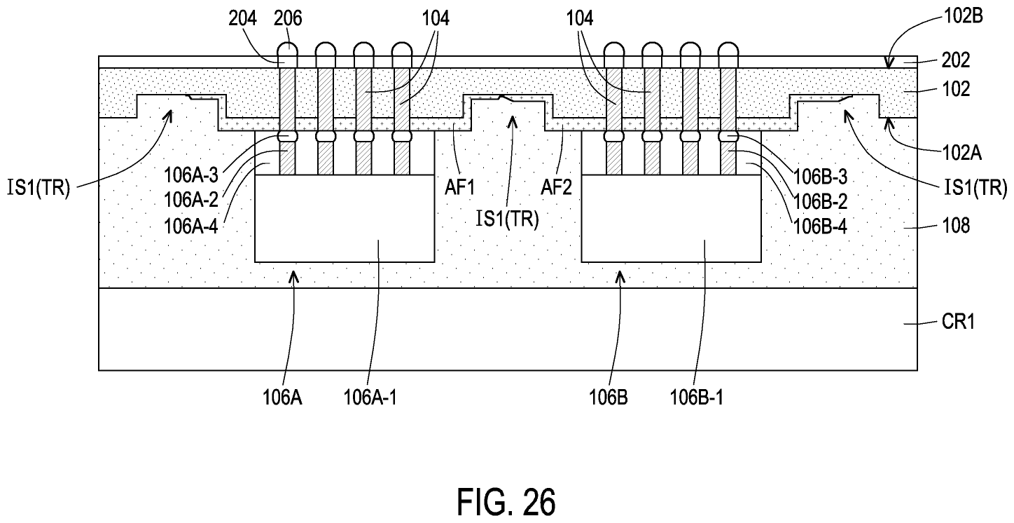

Referring to FIG. 26, in a subsequent step, a dielectric material layer 202 is formed over the second surface 102B of the supporting base 102. In some embodiments, the dielectric material layer 202 may be a polyimide layer, a polybenzoxazole (PBO) layer, a benzocyclobutene (BCB) layer, or other suitable polymer or dielectric layers. In certain embodiments, the dielectric material layer 202 is formed by spin-coating or deposition, including chemical vapor deposition (CVD), plasma-enhanced CVD (PECVD), high-density plasma CVD (HDP-CVD), or the like. In some embodiments, the dielectric material layer 202 is patterned using photolithography techniques and using one or more etching processes to form openings revealing the conductive pillars 104. Thereafter, a plurality of conductive patterns 204 may be filled within the openings, wherein the conductive patterns are electrically connected to the conductive pillars 104. Any excessive conductive materials on the dielectric material layer 202 may be removed, such as by using a chemical mechanical polishing process. In certain embodiments, the conductive patterns 204 includes copper, aluminum, tungsten, silver, or combinations thereof.

As further illustrated in FIG. 26, in some embodiments, a plurality of electrical connectors 206 is disposed on the conductive patterns 204, and are electrically coupled to the conductive pillars 104. In some embodiments, the electrical connectors 206 are placed on the top surface of the dielectric material layer 202, and are electrically connected to the conductive pillars 104 by the conductive patterns 204. In certain embodiments, the electrical connectors 206 are positioned on and physically attached to each of the conductive patterns 204. In some embodiments, the electrical connectors 206 include lead-free solder balls, solder balls, ball grid array (BGA) balls, bumps, controlled collapse chip connection (C4) bumps or micro bumps. In some embodiments, the electrical connectors 206 may include a conductive material such as solder, copper, aluminum, gold, nickel, silver, palladium, tin, or a combination thereof. In some embodiments, the electrical connectors 206 are formed by forming the solder paste on the dielectric material layer 202 by, for example, evaporation, electroplating, printing or solder transfer and then reflowed into the desired bump shapes. In some embodiments, the electrical connectors 206 are placed on the dielectric material layer 202 by ball placement or the like. In other embodiments, the electrical connectors 206 are formed by forming solder-free metal pillars (such as a copper pillar) by sputtering, printing, electroless or electro plating or CVD, and then forming a lead-free cap layer by plating on the metal pillars. The electrical connectors 206 may be used to bond to an external device or an additional electrical component. In some embodiments, the electrical connectors 206 are used to bond to a circuit substrate, a semiconductor substrate or a packaging substrate.

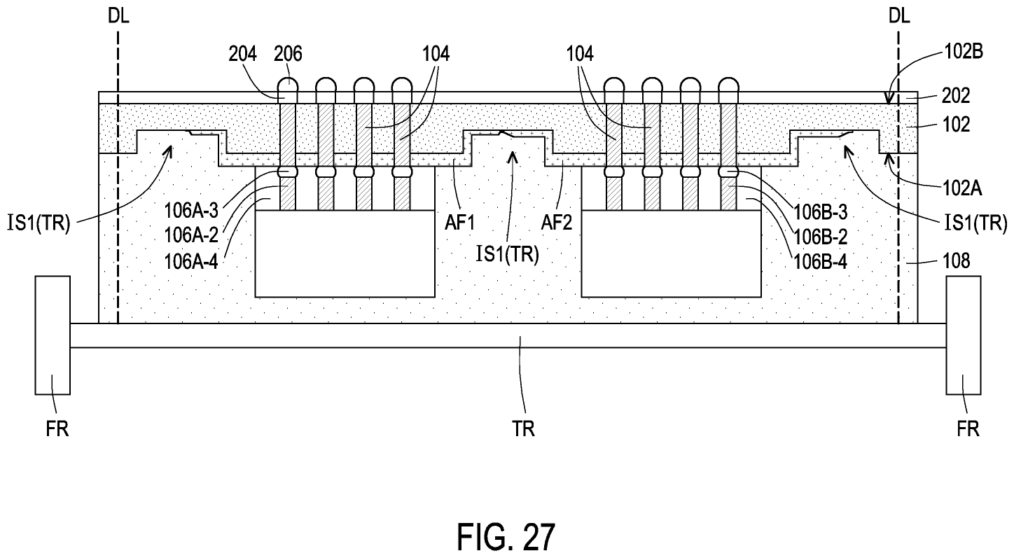

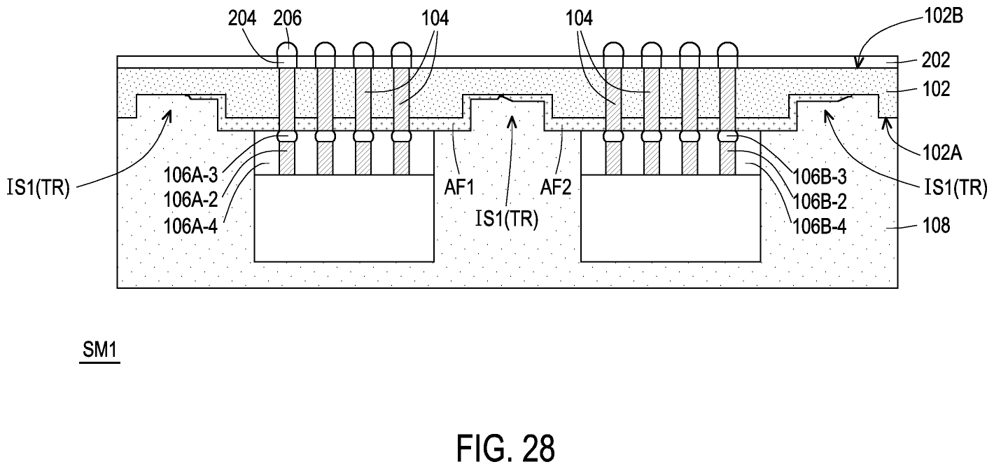

Referring to FIG. 27, in a subsequent step, the carrier CR1 is de-bonded. For example, the de-bonding process includes projecting a light such as a laser light or an UV light on a debond layer (e.g., light-to-heat-conversion release layer) that is attached to the carrier CR1 (not shown), so that the carrier CR1 can be easily removed along with the debond layer. As illustrated in FIG. 27, after de-bonding the carrier CR1, the structure is then attached to a tape TP (e.g., a dicing tape) supported by a frame FR. Thereafter, a dicing process is performed to cut through the dielectric material layer 202, the supporting base 102, and the insulating encapsulant 108 to separate individual devices or packages. In some embodiments, the dicing process or the singulation process typically involves dicing with a rotating blade or a laser beam. In other words, the dicing or singulation process is, for example, a laser cutting process, a mechanical sawing process, or other suitable processes. After the dicing process, the singulated semiconductor device SM1 illustrated in FIG. 28 can be obtained.

Referring to FIG. 28, the singulated semiconductor device SM1 illustrated in FIG. 28 is mounted or attached onto a circuit substrate 300 through the electrical connectors 206. In some embodiments, the circuit substrate 300 include contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

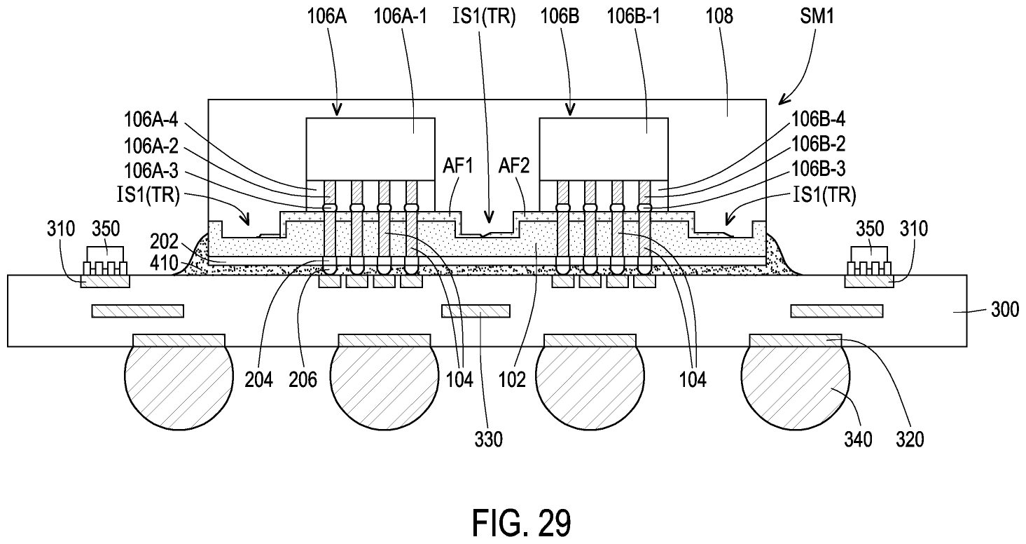

As illustrated in FIG. 29, in the exemplary embodiment, the singulated semiconductor device SM1 is bonded to the circuit substrate 300 through physically connecting the electrical connectors 206 and the contact pads 310 to form a stacked structure, where the semiconductor device SM1 is physically and electrically connected to the circuit substrate 300. In some embodiments, the circuit substrate 300 is such as an organic flexible substrate or a printed circuit board. In such embodiments, the electrical connectors 206 are, for example, chip connectors. In some embodiments, a plurality of conductive balls 340 are respectively formed on the substrate 300. As shown in FIG. 29 for example, the conductive balls 340 are connected to the contact pads 320 of the circuit substrate 300. In other words, the conductive balls 340 are electrically connected to the circuit substrate 300 through the contact pads 320. Through the contact pads 310 and the contact pads 320, some of the conductive balls 340 are electrically connected to the semiconductor device SM1 (e.g. the semiconductor dies included therein). In some embodiments, the conductive balls 340 are, for example, solder balls or BGA balls. In some embodiments, the semiconductor device SM1 is bonded to the circuit substrate 300 through physically connecting the electrical connectors 206 and the contact pads 310 of the circuit substrate 300 by a chip on wafer on substrate (CoWoS) packaging processes. In addition, as illustrated in FIG. 29, one or more passive component 350 (or integrated passive device) may be mounted on the circuit substrate 300. For example, the passive component 350 may be mounted on the contact pads 310 of the circuit substrate 300 through a soldering process. The disclosure is not limited thereto.

In some embodiments, an underfill structure 410 is formed to fill up the spaces in between the circuit substrate 300 and the semiconductor device SM1. In some embodiments, the underfill structure 410 fills up the spaces in between adjacent electrical connectors 206 and covers the electrical connectors 206. In some embodiments, the underfill structure 410 covers and is in physical contact with sidewalls of the supporting base 102. In certain embodiments, the passive component 350 is exposed by the underfill structure 410, and kept a distance apart from the underfill structure 410. In other words, the underfill structure 410 does not cover the passive component 350.

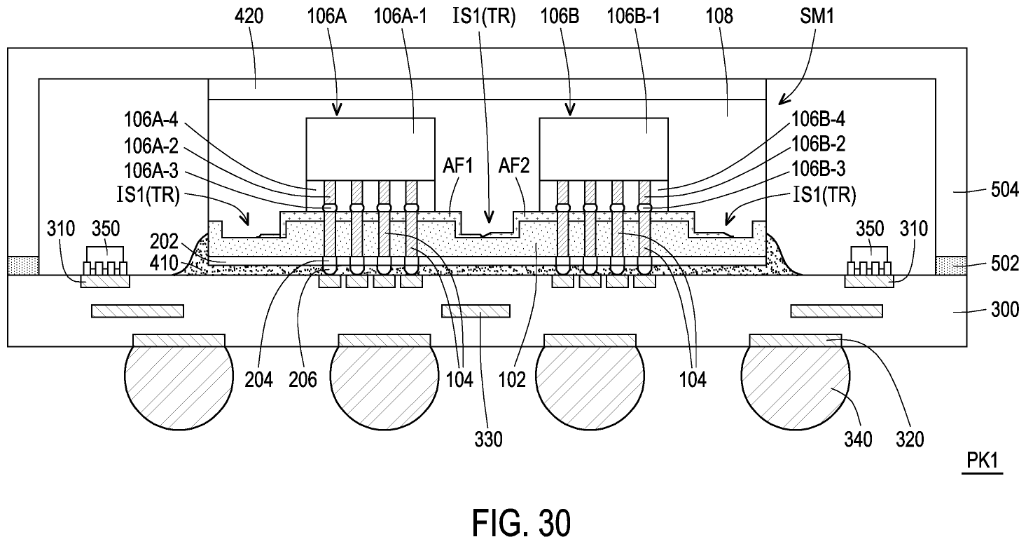

Referring to FIG. 30, after forming the underfill structure 410, a lid structure 504 may be attached to the circuit substrate 300 through an adhesive material 502. In some embodiments, before mounting the lid structure 504 on the circuit substrate 300a thermal interface material 420 is mounted on the backside surface of the semiconductor device SM1. In some embodiments, the thermal interface material 420 may be a polymer having a good thermal conductivity (Tk), which may be between about 3 watts per meter kelvin (W/mK) to about 5 W/mK. In certain embodiments, the thermal interface material 420 may include a polymer with thermal conductive fillers. The thermal conductive fillers may increase the effective Tk of the thermal interface material 420 to be between about 10 W/mK to about 50 W/mK or more. After mounting the lid structure 504 on the circuit substrate 300 and over the thermal interface material 420, a package structure PK1 according to some embodiments of the present disclosure is accomplished.

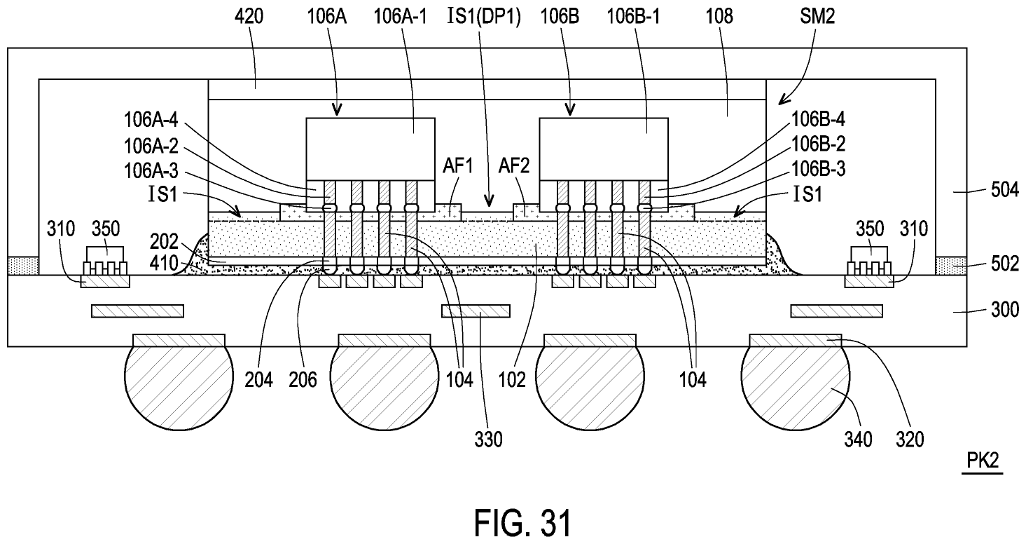

FIG. 31 is a schematic sectional view of a package structure in accordance with some other embodiments of the present disclosure. The package structure PK2 illustrated in FIG. 31 is similar to the package structure PK1 illustrated in FIG. 30. Therefore, the same reference numerals are used to refer to the same or liked parts and its details will not be repeated herein. The difference between the embodiments is that the semiconductor device SM1 is replaced with a singulated semiconductor device SM2. For example, the singulated semiconductor device SM2 is prepared by taking the semiconductor device SM2 obtained in FIG. 10, and performing the same steps illustrated in FIG. 24 to FIG. 28 to form the dielectric material layer 202, the conductive patterns 204 and the electrical connectors 206 over the second surface 102B of the supporting base 102. After mounting the singulated semiconductor device SM2 to the circuit substrate 300 and mounting the lid structure 504 on the circuit substrate 300, a package structure PK2 according to some embodiments of the present disclosure is accomplished.

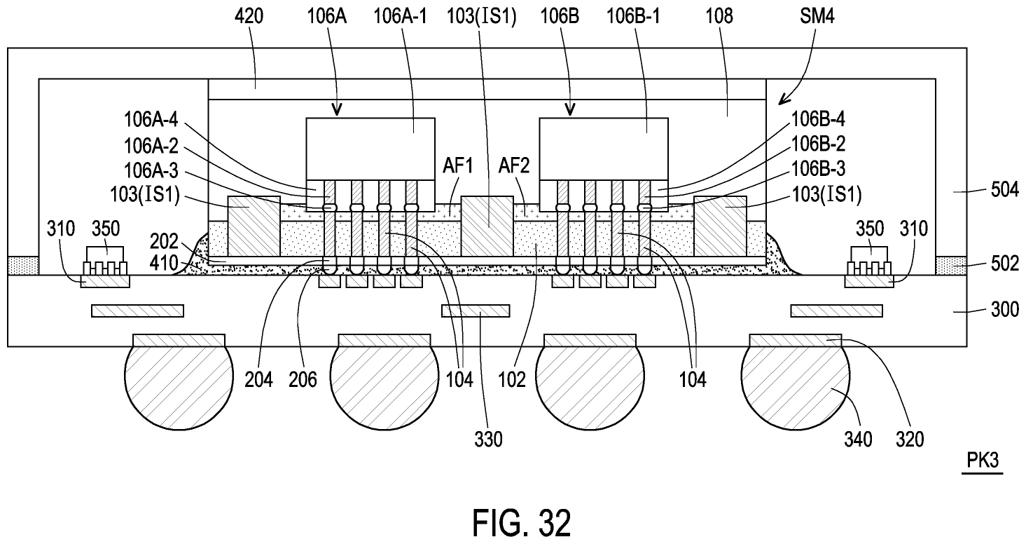

FIG. 32 is a schematic sectional view of a package structure in accordance with some other embodiments of the present disclosure. The package structure PK3 illustrated in FIG. 32 is similar to the package structure PK1 illustrated in FIG. 30. Therefore, the same reference numerals are used to refer to the same or liked parts and its details will not be repeated herein. The difference between the embodiments is that the semiconductor device SM1 is replaced with a singulated semiconductor device SM4. For example, the singulated semiconductor device SM4 is prepared by taking the semiconductor device SM4 obtained in FIG. 16, and performing the same steps illustrated in FIG. 24 to FIG. 28 to form the dielectric material layer 202, the conductive patterns 204 and the electrical connectors 206 over the second surface 102B of the supporting base 102. After mounting the singulated semiconductor device SM4 to the circuit substrate 300 and mounting the lid structure 504 on the circuit substrate 300, a package structure PK3 according to some embodiments of the present disclosure is accomplished.

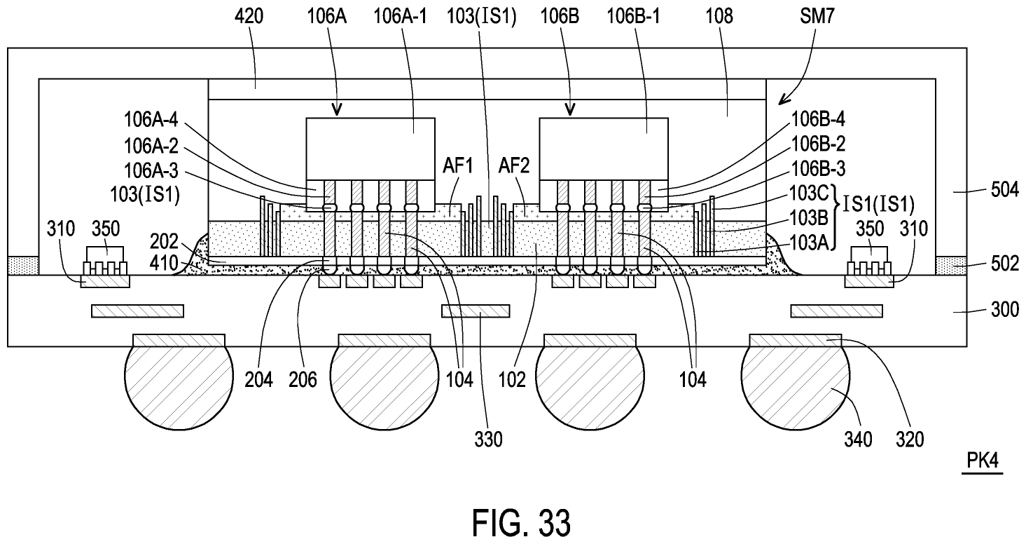

FIG. 33 is a schematic sectional view of a package structure in accordance with some other embodiments of the present disclosure. The package structure PK4 illustrated in FIG. 33 is similar to the package structure PK1 illustrated in FIG. 30. Therefore, the same reference numerals are used to refer to the same or liked parts and its details will not be repeated herein. The difference between the embodiments is that the semiconductor device SM1 is replaced with a singulated semiconductor device SM7. For example, the singulated semiconductor device SM7 is prepared by taking the semiconductor device SM7 obtained in FIG. 23, and performing the same steps illustrated in FIG. 24 to FIG. 28 to form the dielectric material layer 202, the conductive patterns 204 and the electrical connectors 206 over the second surface 102B of the supporting base 102. After mounting the singulated semiconductor device SM7 to the circuit substrate 300 and mounting the lid structure 504 on the circuit substrate 300, a package structure PK4 according to some embodiments of the present disclosure is accomplished.

According to the above embodiments, the semiconductor device or the package structure includes a supporting base and an isolation structure on the supporting base. As such, when bonding semiconductor dies to the conductive pillars on the supporting base, the isolation structure may prevent a bleeding of the adhesive material to any adjacent semiconductor dies. Overall, a risk of tilt, cold joint or voids during the bonding of adjacent dies can be prevented, and the semiconductor device/package structure may have improved reliability.

In accordance with some embodiments of the present disclosure, a package structure includes a supporting base, conductive pillars, a first semiconductor die, a second semiconductor die, a first adhesive material, a second adhesive material and an isolation structure. The conductive pillars are disposed in the supporting base, and protruding out from a top surface of the supporting base. The second semiconductor die is adjacent to the first semiconductor die, wherein the first and second semiconductor dies are disposed on the supporting base and electrically connected to the conductive pillars. The first adhesive material is disposed in between the first semiconductor die and the top surface of the supporting base, and partially covering the conductive pillars. The second adhesive material is disposed in between the second semiconductor die and the top surface of the supporting base, and partially covering the conductive pillars. The isolation structure isolates the first semiconductor die from the second adhesive material, and isolates the second semiconductor die from the first adhesive material.

In accordance with some other embodiments of the present disclosure, a package structure includes a circuit substrate, an interposer structure, conductive pillars, semiconductor dies, an isolation structure and an insulating encapsulant. The interposer is disposed on and electrically connected to the circuit substrate, wherein the interposer structure includes a first surface facing the circuit substrate and a second surface opposite to the first surface. The conductive pillars are disposed in the interposer structure, and protruding out from the second surface of the interposer structure. The semiconductor dies are disposed on the second surface of the interposer structure, wherein each of the semiconductor dies are bonded to the conductive pillars through an adhesive material. The isolation structure is located on the interposer structure and physically separates the adhesive material located on adjacent semiconductor dies. The insulating encapsulant is disposed on the second surface of the interposer structure and encapsulating the plurality of semiconductor dies.

In accordance with yet another embodiment of the present disclosure, a method of fabricating a package structure is described. The method includes the following steps. A supporting base having a plurality of conductive pillars embedded therein is provided. Portions of the supporting base are removed so that the plurality of conductive pillars is protruding out from a top surface of the supporting base, and so that an isolation structure is formed in the supporting base. A first semiconductor die is bonded and electrically connected to the plurality of conductive pillars through a first adhesive material, wherein the first adhesive material is disposed in between the first semiconductor die and the top surface of the supporting base, and partially covering the plurality of conductive pillars. A second semiconductor die is bonded and electrically connected to the plurality of conductive pillars through a second adhesive material, wherein the second adhesive material is disposed in between the second semiconductor die and the top surface of the supporting base, and partially covering the plurality of conductive pillars. The isolation structure isolates the first semiconductor die from the second adhesive material, and isolates the second semiconductor die from the first adhesive material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a supporting base having a top surface;
a plurality of conductive pillars disposed in the supporting base, and protruding out from the top surface of the supporting base;
a first semiconductor die and a second semiconductor die adjacent to the first semiconductor die, wherein the first semiconductor die and the second semiconductor die are disposed on the supporting base and electrically connected to the plurality of conductive pillars;
a first adhesive material disposed in between the first semiconductor die and the top surface of the supporting base, and partially covering the plurality of conductive pillars;
a second adhesive material disposed in between the second semiconductor die and the top surface of the supporting base, and partially covering the plurality of conductive pillars; and
an isolation structure located on the supporting base, wherein the isolation structure isolates the first semiconductor die from the second adhesive material, and isolates the second semiconductor die from the first adhesive material.

2. The package structure according to claim 1, wherein the isolation structure includes isolation trenches located on the top surface of the supporting base, the isolation trenches separate the first semiconductor die from the second semiconductor die, and wherein the first adhesive material and the second adhesive material fills into the isolation trenches.

3. The package structure according to claim 1, wherein the isolation structure includes dam structures that separates the first semiconductor die from the second semiconductor die, and wherein at least one of the first adhesive material and the second adhesive material physically contact sidewalls of the dam structures.

4. The package structure according to claim 3, wherein the dam structures are metal dam structures surrounding the first semiconductor die and the second semiconductor die.

5. The package structure according to claim 4, wherein the metal dam structures comprise a first metal dam portion encircling the first semiconductor die, a second metal dam portion encircling the first metal dam portion, and a third metal dam portion encircling the second metal dam portion.

6. The package structure according to claim 3, wherein the dam structures extend to a level higher than top surfaces of the plurality of conductive pillars.

7. The package structure according to claim 1, wherein the first adhesive material covers and contacts sidewalls of the first semiconductor die, and the second adhesive material covers and contacts sidewalls of the second semiconductor die.

8. The package structure according to claim 1, wherein the first adhesive material and the second adhesive material includes non-conductive films (NCF) or non-conductive pastes (NCP).

9. A package structure, comprising:
a circuit substrate;
an interposer structure disposed on and electrically connected to the circuit substrate, wherein the interposer structure comprises a first surface facing the circuit substrate and a second surface opposite to the first surface;
a plurality of conductive pillars disposed in the interposer structure, and protruding out from the second surface of the interposer structure;
a plurality of semiconductor dies disposed on the second surface of the interposer structure, wherein each of the plurality of semiconductor dies is bonded to the plurality of conductive pillars through an adhesive material;
an isolation structure located on the interposer structure, wherein the isolation structure physically separates the adhesive material located on adjacent semiconductor dies in the plurality of semiconductor dies; and
an insulating encapsulant disposed on the second surface of the interposer structure and encapsulating the plurality of semiconductor dies.

10. The package structure according to claim 9, wherein the adhesive material is covering and contacting a portion of the plurality of conductive pillars, and is in physical contact with the isolation structure.

11. The package structure according to claim 9, wherein the isolation structure includes dam structures that separates the plurality of semiconductor dies from one another.

12. The package structure according to claim 11, wherein the dam structures comprise a first dam portion that is surrounding four sidewalls of at least one of the plurality of semiconductor dies.

13. The package structure according to claim 12, wherein the dam structures further comprise a second dam portion that is surrounding the first dam portion, and the adhesive material is in contact with the second dam portion.

14. The package structure according to claim 9, wherein the adhesive material located under one semiconductor die of the plurality of semiconductor dies extends over a first sidewall of the one semiconductor die by a first distance, and extends over a second sidewall of the one semiconductor die by a second distance, and the second distance is different from the first distance.

15. The package structure according to claim 9, wherein the second surface of the interposer structure includes a plurality of recessed portions, and the plurality of conductive pillars is protruding out from the plurality of recessed portions at the second surface of the interposer structure, and wherein each of the plurality of semiconductor dies is respectively disposed on each of the plurality of recessed portions.

16. A method of fabricating a package structure, comprising:
providing a supporting base having a plurality of conductive pillars embedded therein;
removing portions of the supporting base so that the plurality of conductive pillars is protruding out from a top surface of the supporting base, and so that an isolation structure is formed on the supporting base;
bonding and electrically connecting a first semiconductor die to the plurality of conductive pillars through a first adhesive material, wherein the first adhesive material is disposed in between the first semiconductor die and the top surface of the supporting base, and partially covering the plurality of conductive pillars;
bonding and electrically connecting a second semiconductor die to the plurality of conductive pillars through a second adhesive material, wherein the second adhesive material is disposed in between the second semiconductor die and the top surface of the supporting base, and partially covering the plurality of conductive pillars, and
wherein the isolation structure isolates the first semiconductor die from the second adhesive material, and isolates the second semiconductor die from the first adhesive material.

17. The method according to claim 16, wherein the isolation structure is formed by removing portions of the supporting base to form isolation trenches on the top surface of the supporting base, the isolation trenches separate the first semiconductor die from the second semiconductor die, and the first adhesive material and/or the second adhesive material fills into the isolation trenches after bonding the first semiconductor die and the second semiconductor die.

18. The method according to claim 16, wherein the supporting base further comprises metal dam structures embedded therein, and forming the isolation structure comprises removing portions of the supporting base so that the metal dam structures are revealed from the supporting base, and the metal dam structures are used as the isolation structure for isolating the first adhesive material from the second adhesive material.

19. The method according to claim 18, wherein after bonding the first semiconductor die and the second semiconductor die, the first adhesive material and the second adhesive material flow towards sidewalls of the metal dam structures to physically contact the sidewalls of the metal dam structures.

20. The method according to claim 16, wherein removing the portions of the supporting base comprises forming a plurality of recessed portions on the top surface of the supporting base, and the bonding of the first semiconductor die and the second semiconductor die comprises bonding the first semiconductor die and the second semiconductor die over the recessed portions of the supporting base.
